(19) United States
(12) Patent Application Publication
(10) Pub. No.: US 2010/0273535 A1
(43) Pub. Date: Oct. 28, 2010

(54) RADIO-FREQUENCY POWER AMPLIFIER DEVICE AND WIRELESS COMMUNICATION DEVICE INCLUDING THE SAME

(75) Inventors: Masahiko INAMORI, Osaka (JP); Motoyoshi IWATA, Osaka (JP); Kaname MOTOYOSHI, Hyogo (JP); Masahiro MAEDA, Osaka (JP); Yorito OTA, Hyogo (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/758,877

(22) Filed: Apr. 13, 2010

(30) Foreign Application Priority Data
Apr. 22, 2009 (JP) 2009-103945
Jan. 29, 2010 (JP) 2010-019107

(51) Int. Cl. H04B 1/38; H03F 3/68; H04W 88/06

(52) U.S. Cl. 455/571; 330/126; 330/295

(57) ABSTRACT

A radio-frequency power amplifier device includes an input terminal for which a first radio-frequency signal for a CDMA mode within a first frequency band and a third radio-frequency signal for a TDMA mode within the first frequency band are selectively provided, a second input terminal for which a second radio-frequency signal for a CDMA mode within a second frequency band and a fourth radio-frequency signal for a TDMA mode within the second frequency band are selectively provided, a first power amplifier unit which to amplifies the provided first radio-frequency signal, a second power amplifier unit which amplifies the provided second radio-frequency signal, a third power amplifier unit which amplifies the provided third radio-frequency signal, and a fourth power amplifier unit which amplifies the provided fourth radio-frequency signal. These power amplifier units are arranged in order of the first power amplifier unit to the fourth power amplifier unit.

### BACKGROUND OF THE INVENTION

(1) Field of the Invention

The present invention relates to radio-frequency power amplifier devices to be used for power amplification of radio frequency signals.

(2) Description of the Related Art

Digital mobile phone terminals which support multi bands (for example, a band centered at 2 GHz and a band centered at 900 MHz) or multi-mode systems (for example, Global System for Mobile Communications (GSM), Digital Communication System (DCS), and Universal Mobile Transmission Standard (UMTS)) to allow for global use are rapidly becoming popular. In mobile phone terminals, a typical high-output transmit power amplifier unit has a configuration in which two or three semiconductor transistors for radio-frequency amplification are connected in multi stages. In order to support multi bands or multi modes, various power amplifier units and wireless communication devices using such power amplifier units have been investigated (see Patent Reference 1, Japanese Unexamined Patent Application Publication No. 2005-294894, and Patent Reference 2, Japanese Unexamined Patent Application Publication No. 2001-186042).

Generally, transmit output power of power amplifier units ranges as widely as follows: approximately +35 dBm for a GSM mode, approximately +33 dBm for a DCS mode, and approximately +27 dBm to −50 dBm for a UMTS mode. The transmit output power has the strongest influences on receive units in the mobile phone terminal most at +35 dBm (GSM), +33 dBm (DCS), and +27 dBm (UMTS) at which the output power peaks. It is thus necessary to reduce the influences from or near to output units of the power amplifier units on the receive unit.

A power amplifier unit of a mobile phone which supports multi bands or multi modes is provided with a configuration in which radio-frequency transmit circuits (RF transmit circuits) include power amplifier units and are connected in parallel in order to secure radio-frequency characteristics (RF characteristics). FIG. 14 shows an exemplary configuration of a mobile communication terminal having a conventional radio-frequency power amplifier unit (RF power amplifier unit) and a wireless communication device including the RF power amplifier unit.

FIG. 14 is a block diagram which shows a configuration of a mobile communication terminal described in Patent Reference 1.

A mobile communication terminal 800 shown in FIG. 14 includes a microphone 801, a speaker 806, an RF power amplifier unit 810, an antenna switch 813, an antenna 814, a radio-frequency integrated circuit (RFIC) 815 which converts a baseband signal to a radio-frequency signal (RF signal) or an RF signal to a baseband signal, a baseband signal processing device 816, a duplexer 817a, filters 818a and 818b, matching circuits 820 and 821, a switch 830, filters 840b, 840c, 840d, and 840f, a gain control unit 860, radio-frequency receive circuit devices 8120 to 8122, and a transmission circuit 8130.

The components enclosed in a dashed line box form a first transmit path 8110. A combination of components including the filter 818a and enclosed in one of alternate long and short dashed line boxes forms a second transmit path 8111. A combination of components including the filter 818b and enclosed in the other one of alternate long and short dashed line boxes forms a third transmit path 8112

The mobile communication terminal 800 uses the first transmit path 8110 including the duplexer 817a for communication in a UMTS mode (in a 2-GHz band, for example) using an access method of code division multiple access (CDMA), the third transmit path 8112 including the filter 818b and the second transmit path 8111 including the filter 818a respectively for communication in a GSM mode (in a 900-MHz band, for example) and in a DCS mode (in a 1.8-GHz band, for example) using an access method of time division multiple access (TDMA).

Problems with such multi-band or multi-mode mobile communication terminals include reduction in cost and size. In order to address the problem, techniques have been developed that use a single input path for receiving two bands of relatively close frequencies when the RF power amplifier unit 810 receives from the RFIC 815 RF signals having relatively close frequency bands (for example, a 2-GHz band and a 1.8-GHz band, a 850-MHz band and a 900-MHz band) for these years.

A possible way is, for example, that a single input path without the filter 840c is used for receiving two RF signal inputs (one is an input in the UMTS mode in the 2-GHz band, and the other is an input in the DCS mode in the 1.8-GHz band) from the RFIC 815 to the RF power amplifier unit 810 shown in FIG. 14.

In this case, although performance enhancement of the RFIC 815 is required, reduction in cost and size is expected because an interface between the RFIC 815 and the RF power amplifier unit 810 is simplified and the number of terminals is accordingly reduced.

In other words, such a configuration provides a downsized and low-cost mobile communication terminal which amplifies power for transmission while supporting multi bands or multi modes.

When a global trend toward multi bands or multi modes accelerates, the three transmit paths used in the conventional mobile communication terminal are expected to become insufficient.

However, there will be a problem when another path for the UMTS mode (in an 850-MHz band, for example) is added to the conventional mobile communication terminal. The problem is as follows.

First, in order to clarify the problem, a configuration of a mobile communication terminal is described below in which another path for the UMTS mode (in an 850-MHz band, for example) is added to the conventional mobile communication terminal.

FIG. 15 is a drawing which shows a configuration of part of a conventional mobile communication terminal to which a path for the UMTS mode in the 850-MHz band is added, or, more specifically, a schematic diagram which shows a layout of a wireless communication device including all the blocks of the mobile communication terminal except a microphone and a speaker.

Compared with the mobile communication terminal shown in FIG. 14, a wireless communication device 900 shown in FIG. 15 further has a path for the UMTS mode in the 850-MHz band. The wireless communication device 900 includes a transmit unit 911, a receive unit 912, an antenna switch 913, an antenna 914, an RFIC 915, a baseband large-scale integration (LSI) 916, duplexers 917a and 917b, and filters 918a and 918b. One of input paths from the RFIC 915 to the transmit unit 911 is used for RF signals of relatively high frequency bands of the 2-GHz band and the 1.8-GHz band in common. The other is used for relatively low frequency bands of the 900-MHz band and the 850-MHz band in common.

A configuration of the transmit unit 911 in FIG. 15 is equivalent to a configuration in which a circuit involved in transmission in the UMTS mode in the 850-MHz band is added to whole circuitry involved in transmission of the mobile communication terminal 800 shown in FIG. 14. On the other hand, a configuration of the receive unit 912 is equivalent to a configuration in which a circuit involved in reception in the UMTS mode in the 850-MHz band is added to whole circuitry involved in reception of the mobile communication terminal 800 shown in FIG. 14.

This means that the wireless communication device 900 is identical to the mobile communication terminal shown in FIG. 14 with an exception that the wireless communication device 900 lacks a microphone and a speaker but has a path for the UMTS mode in the 850-MHz band.

The path from the transmit unit 911 to the duplexer 917a is hereinafter referred to as a first transmit path 9110. The path from the transmit unit 911 to the antenna switch 913 via the filter 918a is hereinafter referred to a second transmit path 9111. The path from the transmit unit 911 to the antenna switch 913 via the filter 918b is hereinafter referred to as a third transmit path 9112. The path from the transmit unit 911 to the duplexer 917b is hereinafter referred to as a fourth transmit path 9113. The path from the duplexer 917b to the receive unit 912 is hereinafter referred to as a receive path 9123.

In the case where the path for the UMTS mode is added to the configuration of the conventional mobile communication terminal, the fourth transmit path 9113 including the added duplexer 917b may be disposed between the third transmit path 9112 including the filter 918b and the second transmit path 9111 including the filter 918a as shown in a layout of the wireless communication device 900 shown in FIG. 15. In another possible layout of the wireless communication device 900 which differs from the one shown in FIG. 15, the third transmit path 9112 including the filter 918b may be disposed between the fourth transmit path 9113 including the added duplexer 917b and the second transmit path 9111 including the filter 918a.

In these layouts, however, sufficient isolation cannot be provided between the second transmit path 9111 and the receive path 9123 because the second transmit path 9111 and the receive path 9123 intersects on the board.

FIG. 16 is a schematic view which shows an exemplary layout of the transmit unit 911, the receive unit 912, the antenna switch 913, the duplexers 917a and 917b, and the filters 918a and 918b included in the wireless communication device 900 shown in FIG. 15. In this layout, they are disposed on a board.

As shown in FIG. 16, blocks (the transmit unit 911, the receive unit 912, the antenna switch 913, the duplexers 917a and 917b, the filters 918a and 918b ) are disposed on, for example, a multilayer printed circuit board (multilayer PCB) 920. This schematic view shows that the second transmit path 9111 and the receive path 9123 intersect on the multilayer PCB 920.

The filters 918a and 918b are usually provided so as to suppress harmonics of RF signals. Thus, at the second transmit path 9111 including the filter 918a, a relatively high power is outputted in a reception band as well.

In this case, the transmission power may leak into the receive path 9123, which has the intersection with the transmit path 9111, and be propagated into the receive unit 912 through the receive path 9123 when the transmit unit 911 selects the DCS mode and the transmit unit 911 provides a maximum output power of +33 dBm for the second transmit path 9111. The receive unit 912 has power amplifier units: an RxHC, an RxLC, and an RxHT. At this time, the power amplifier unit RxHT, which corresponds to the DCS mode, operates but the power amplifier unit RxLC, which is connected to the receive path 9123, does not.

The receive unit 912 handles, however, a reception power on the order of −20 dBm, which is as small as one hundred thousandth of the transmit power handled by the transmit unit 911. The receive unit 912 is thus required to have a high reception sensitivity.

Thus, even leakage power in the DCS mode propagated through the receive path 9123 reaches to the power amplifier unit RxHT for the DCS mode when the receive unit 912 receives the leakage power. This problematically decreases the receiving sensitivity of the receive unit 912.

It is noted that there is not such a severe problem as described above with intersections between the receive path 9123 and the transmission-and-receive path and between the duplexer 917a and the antenna switch 913 on the multilayer PCB 920 as shown in FIG. 15 and FIG. 16 because output components of the transmission power into the reception band are suppressed in the transmission-and-receive path between the duplexer 917a and the antenna switch 913 and the transmission-and-receive path between the duplexer 917b and the antenna switch 913.

The present invention has an object of solving the problem with the conventional techniques and providing a radio-frequency power amplifier device (RF power amplifier device) which supports multi bands and multi modes and reduces degradation of reception sensitivity and a wireless communication device in which the RF power amplifier device is used.

### SUMMARY OF THE INVENTION

The RF power amplifier device according to the present invention amplifies power of high-frequency signals for communication modes including a first mode and a second mode which is a communication method different from the first mode and includes: a first input terminal to which a first RF signal for the first mode and within a first frequency band and a third RF signal for the second mode and within the first frequency band are selectively provided; a second input terminal to which a second RF signal for the first mode and within a second frequency band and a fourth RF signal for the second mode and within the second frequency band are selectively provided, the second frequency band being different from the first frequency band; a first power amplifier unit configured to amplify the first RF signal provided to the first input terminal; a second power amplifier unit configured to amplify the second RF signal provided to the second input terminal; a third power amplifier unit configured to amplify the third RF signal provided to the first input terminal; and a fourth power amplifier unit configured to amplify the fourth RF signal provided to the second input terminal, wherein the first to fourth power amplifier units are arranged in order of the first power amplifier unit, the second power amplifier unit, the third power amplifier unit, and the fourth power amplifier unit.

With this, an RF signal transmitted in one of the first mode and the second mode is prevented from leaking into the receive path of an RF signal for the other one of the first mode and the second mode.

For example, this configuration has no intersection between the second transmit path 9111 and the receive path 9123 as shown in FIG. 16, thus preventing leakage of the RF signal from the second transmit path 9111 into the receive path 9123. Degradation of reception sensitivity is thereby reduced.

This also reduces decrease in the transmission power of the RF signal in the one of the first mode and the second mode.

It is also possible that the first to fourth power amplifier units are formed on at least one semiconductor substrate, the RF power amplifier device further includes: a board on which the at least one semiconductor substrate is mounted; a receive unit mounted on the board; a first transmit line formed on the at least one semiconductor substrate and having a first end connected to an output terminal of the first power amplifier unit; a second transmit line formed on the at least one semiconductor substrate and having a first end connected to an output terminal of the second power amplifier unit; a third transmit line formed on the at least one semiconductor substrate and having a first end connected to an output terminal of the third power amplifier unit; and a fourth transmit line formed on the at least one semiconductor substrate and having a first end connected to an output terminal of the fourth power amplifier unit, the first to fourth transmit lines have no intersection with each other, and the receive unit is disposed closer to the first transmit line and the second transmit line than to the third transmit line and the fourth transmit line.

The RF power amplifier device may further includes a fifth transmit line formed on the board and having a first end connected to a second end of the first transmit line; a sixth transmit line formed on the board and having a first end connected to a second end of the second transmit line; a seventh transmit line formed on the board and having a first end connected to a second end of the third transmit line; an eighth transmit line formed on the board and having a first end connected to a second end of the fourth transmit line; a first receive line and a second receive line formed on the board and each having a first end connected to the receive unit; a first duplexer being mounted on the board and having a first transmission terminal, a first transmit-receive terminal, and a first reception terminal, the first transmission terminal being connected to a second end of the fifth transmit line, and the first reception terminal being connected to a second end of the first receive line; a second duplexer being mounted on the board and having a second transmission terminal; and a second transmit-receive terminal, and a second reception terminal, the second transmission terminal being connected to a second end of the sixth transmit line, and the second reception terminal being connected to a second end of the second receive line, wherein the first receive line has no intersection with the seventh transmit line or the eighth transmit line, and the second receive line has no intersection with the seventh transmit line or the eighth transmit line.

With this, the third RF signal which is being transmitted is prevented from leaking into the first receive line and the second receive line. In the same way, the fourth RF signal being transmitted is prevented from leaking into the first receive line and the second receive line. Degradation of reception sensitivity is thereby reduced.

It is also possible that the first receive line is disposed at a distance of 100 μm or longer from both of the seventh transmit line and the eighth transmit line, and the second receive line is disposed at a distance of 100 μm or longer from both of the seventh transmit line and the eighth transmit line.

This enhances isolation between the first receive line and the seventh transmit line and isolation between the first receive line and the eighth transmit line. In the same way, this enhances isolation between the second receive line and the seventh transmit line and isolation between the second receive line and the eighth transmit line. Degradation of reception sensitivity is thereby further reduced.

It is also possible that the first receive line is formed in a wiring layer in which neither the seventh transmit line nor the eighth transmit line is formed, and the second receive line is formed in a wiring layer in which neither the seventh transmit line nor the eighth transmit line is formed.

This reduces the leakage of the third RF signal and the fourth RF signal into the first receive line and the second receive line due to air propagation of the transmission power of the third RF signal and the fourth RF signal.

It is also possible that the at least one semiconductor substrate includes a first semiconductor substrate and a second semiconductor substrate, the first power amplifier unit and the second power amplifier unit are formed on the first semiconductor substrate, and the third power amplifier unit and the fourth power amplifier unit are formed on the second semiconductor substrate.

This enhances output isolation between the power amplifier units formed on different semiconductor substrates. More specifically, this enhances isolation between the first power amplifier unit formed on the first semiconductor substrate and the third and the fourth power amplifier units formed on the second semiconductor substrate. This also enhances isolation between the second power amplifier unit formed on the first semiconductor substrate and the third and the fourth power amplifier units formed on the second semiconductor substrate. As a result, RF characteristics are enhanced.

It is also possible that the at least one semiconductor substrate includes a first semiconductor substrate, a second semiconductor substrate, and a third semiconductor substrate, the first power amplifier unit is formed on the first semiconductor substrate, the second power amplifier unit is formed on the second semiconductor substrate, and the third power amplifier unit and the fourth power amplifier unit are formed on the third semiconductor substrate.

This enhances isolation between the first power amplifier unit and the second power amplifier unit. As a result, the RF characteristics are further enhanced.

It is also possible that the at least one semiconductor substrate includes a first semiconductor substrate, a second semiconductor substrate, and a third semiconductor substrate, the first power amplifier unit and the second power amplifier unit are formed on the first semiconductor substrate, the third power amplifier unit is formed on the second semiconductor substrate, and the fourth power amplifier unit is formed on the third semiconductor substrate.

This enhances isolation between the third power amplifier unit and the fourth power amplifier unit. As a result, the RF characteristics are further enhanced.

It is also possible that the at least one semiconductor substrate includes a first semiconductor substrate, a second semiconductor substrate, a third semiconductor substrate, and a fourth semiconductor substrate, the first power amplifier unit is formed on the first semiconductor substrate, the second power amplifier unit is formed on the second semiconductor substrate, the third power amplifier unit is formed on the third semiconductor substrate, and the fourth power amplifier unit is formed on the fourth semiconductor substrate.

This also enhances isolation between two of the first to the fourth power amplifier units. As a result, the RF characteristics are further enhanced.

The RF power amplifier device may further includes a first input line having a first end connected to the first input terminal and a second end connected to an input terminal of the first power amplifier unit; a second input line having a first end connected to the second input terminal and a second end connected to an input terminal of the second power amplifier unit; a third input line having a first end connected to the first input line and a second end connected to an input terminal of the third power amplifier unit; and a fourth input line having a first end connected to the second input line and a second end connected to an input terminal of the fourth power amplifier unit, wherein the first end of the third input line is connected to the first input line in the at least one semiconductor substrate, and the first end of the fourth input line is connected to the second input line in the at least one semiconductor substrate.

This allows reduction in size of the RF power amplifier device.

It is also possible that the at least one semiconductor substrate includes a first semiconductor substrate and a second semiconductor substrate, the first power amplifier unit and the second power amplifier unit are formed on the first semiconductor substrate, the third power amplifier unit and the fourth power amplifier unit are formed on the second semiconductor substrate, the first end of the third input line is connected to the first input line in the first semiconductor substrate, and the first end of the fourth input line is connected to the second input line in the second semiconductor substrate.

It is also possible that the at least one semiconductor substrate includes a first semiconductor substrate and a second semiconductor substrate, the first power amplifier unit and the second power amplifier unit are formed on the first semiconductor substrate, the third power amplifier unit and the fourth power amplifier unit are formed on the second semiconductor substrate, the first end of the third input line is connected to the first input line in one of the first semiconductor substrate and the second semiconductor substrate, and the first end of the fourth input line is connected to the second input line in the one of the first semiconductor substrate and the second semiconductor substrate.

This allows further reduction in size of the RF power amplifier device.

It is also possible that each of the first power amplifier unit and the second power amplifier unit includes m multi-stage amplifier elements, where m is a natural number, each of the third power amplifier unit and the fourth power amplifier unit includes n multi-stage amplifier elements, where n is a natural number greater than m, the radio-frequency power amplifier device, so as to supply power to each of the m amplifier element and the n amplifier elements, further includes: m first power lines provided to all of the first to fourth power amplifier units; and (n-m) second power lines provided to both of the third power amplifier unit and the fourth power amplifier unit, and the m first power lines have no intersection with the (n-m) second power lines.

This allows simplification of the layout of the first power line and the second power line.

It is also possible that the at least one semiconductor substrate includes a first semiconductor substrate and a second semiconductor substrate, the first power amplifier unit and the second power amplifier unit are formed on the first semiconductor substrate, and the third power amplifier unit and the fourth power amplifier unit are formed on the second semiconductor substrate.

This configuration makes a power supply pad for the second power line unnecessary for the first semiconductor substrate, thus the first semiconductor substrate can be formed undersized. As a result, the RF power amplifier device can be reduced in size.

The first mode may be a Code Division Multiple Access (CDMA) mode and the second mode may be Time Division Multiple Access (TDMA) mode.

The RF power amplifier device may further includes: a fifth power amplifier unit configured to amplify the fifth RF signal for the first mode; a fifth power amplifier unit configured to amplify the fifth RF signal for the first mode; and a seventh power amplifier unit configured to amplify the seventh RF signal for the first mode, wherein the first frequency band and the second frequency band include five communication bands, the five communication bands correspond to the first power amplifier unit, the second power amplifier unit, and the fifth to seventh power amplifier units on a one-to-one basis, and the five communication bands correspond to the first RF signal, the second RF signal, and the fifth to seventh RF signals on a one-to-one basis, wherein the fifth power amplifier unit to the seventh power amplifier units, the first power amplifier unit, and the second power amplifier unit are arranged in order of the fifth power amplifier unit, the sixth power amplifier unit, the seventh power amplifier unit, the first power amplifier unit, and the second power amplifier unit.

Furthermore, the present invention may be implemented not only as the RF power amplifier device described above but also as a wireless communication device including the RF power amplifier device.

The present invention provides an RF power amplifier device which supports multi bands and multi modes with reduced degradation of reception sensitivity and a wireless communication device in which the RF power amplifier device is used.

### FURTHER INFORMATION ABOUT TECHNICAL BACKGROUND TO THIS APPLICATION

The disclosure of Japanese Patent Application No. 2009-103945 filed on Apr. 22, 2009 and the disclosure of Japanese Patent Application No. 2010-019107 filed on Jan. 29, 2010 including specification, drawings and claims are incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram which schematically shows a configuration of the wireless communication device including the RF power amplifier device according to Embodiment 1 and a layout of the wireless communication device on a board;

FIG. 2 is a block diagram which schematically shows a specific circuit configuration and a layout of the RF power amplifier unit on a board;

FIG. 3A shows an exemplary layout of the RF power amplifier device;

FIG. 3B shows another exemplary layout of the RF power amplifier device;

FIG. 4 is a block diagram which schematically shows a configuration of the wireless communication device including the RF power amplifier device according to Variation of Embodiment 1 and a layout of the wireless communication device on a board;

FIG. 5 is a block diagram which schematically shows a specific circuit configuration and a layout of the RF power amplifier unit on a board;

FIG. 6A schematically shows an exemplary circuit configuration of the RF power amplifier unit included in the RF power amplifier device according to Embodiment 2 and a layout thereof on a board;

FIG. 6B schematically shows another exemplary circuit configuration of the RF power amplifier unit and another exemplary layout thereof on a board;

FIG. 6C schematically shows another exemplary circuit configuration of the RF power amplifier unit and another exemplary layout thereof on a board;

FIG. 6D schematically shows another exemplary circuit configuration of the RF power amplifier unit and another exemplary layout thereof on a board;

FIG. 6E schematically shows another exemplary circuit configuration of the RF power amplifier unit and another exemplary layout thereof on a board;

FIG. 6F schematically shows another exemplary circuit configuration of the RF power amplifier unit and another exemplary layout thereof on a board;

FIG. 6G schematically shows another exemplary circuit configuration of the RF power amplifier unit and another exemplary layout thereof on a board;

FIG. 7 schematically shows an exemplary circuit configuration of the RF power amplifier unit included in the RF power amplifier device according to Embodiment 3 and a layout thereof on a board;

FIG. 8 is a circuit diagram which shows a circuit configuration of a power amplifier unit in detail;

FIG. 9 schematically shows an exemplary circuit configuration of an RF power amplifier unit according to a comparative example for Embodiment 3 and a layout thereof on a board;

FIG. 10 schematically shows another exemplary circuit configuration of an RF power amplifier unit included in the RF power amplifier device according to Embodiment 3 and a layout thereof on a board;

FIG. 11 schematically shows an exemplary circuit configuration of the RF power amplifier unit included in an RF power amplifier device according to Embodiment 4 and a layout thereof on a board;

FIG. 12 schematically shows an exemplary circuit configuration of an RF power amplifier unit according to a comparative example for Embodiment 4 and a layout thereof on a board;

FIG. 13 schematically shows another exemplary circuit configuration of the RF power amplifier unit and another exemplary layout thereof on a board;

FIG. 14 is a block diagram which shows a configuration of a conventional mobile communication terminal;

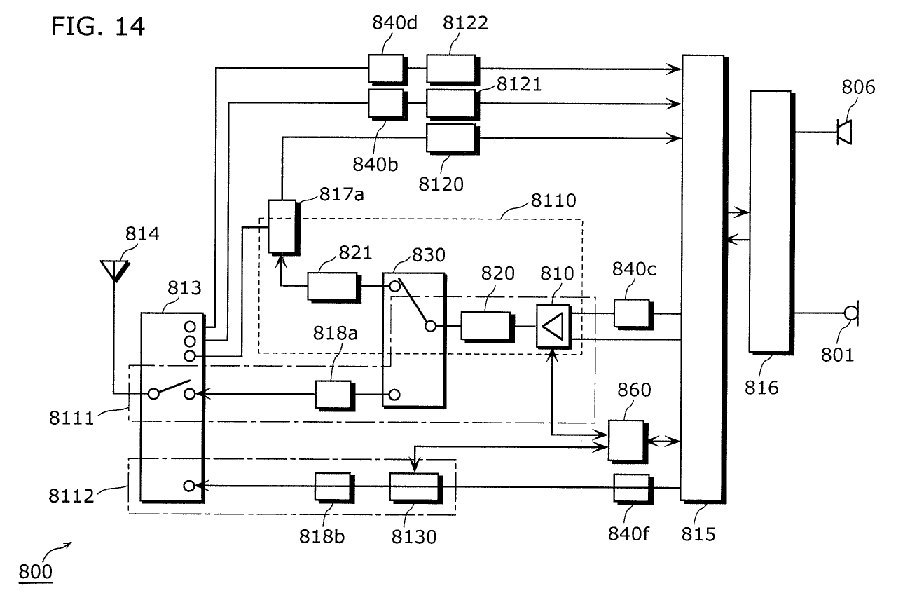

FIG. 15 is a block diagram which shows a configuration of part of a mobile communication terminal for the purpose of describing a problem; and

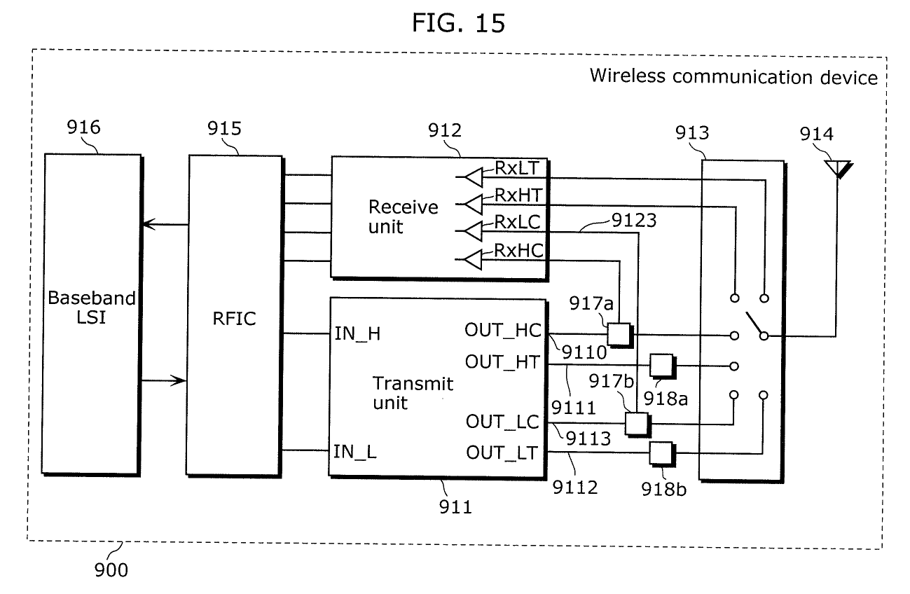

FIG. 16 is a block diagram which shows a layout of the configuration of part of the mobile communication terminal for the purpose of describing the problem.

### DESCRIPTION OF THE PREFERRED EMBODIMENTS

Embodiments of the present invention are described below with reference to drawings.

### Embodiment 1

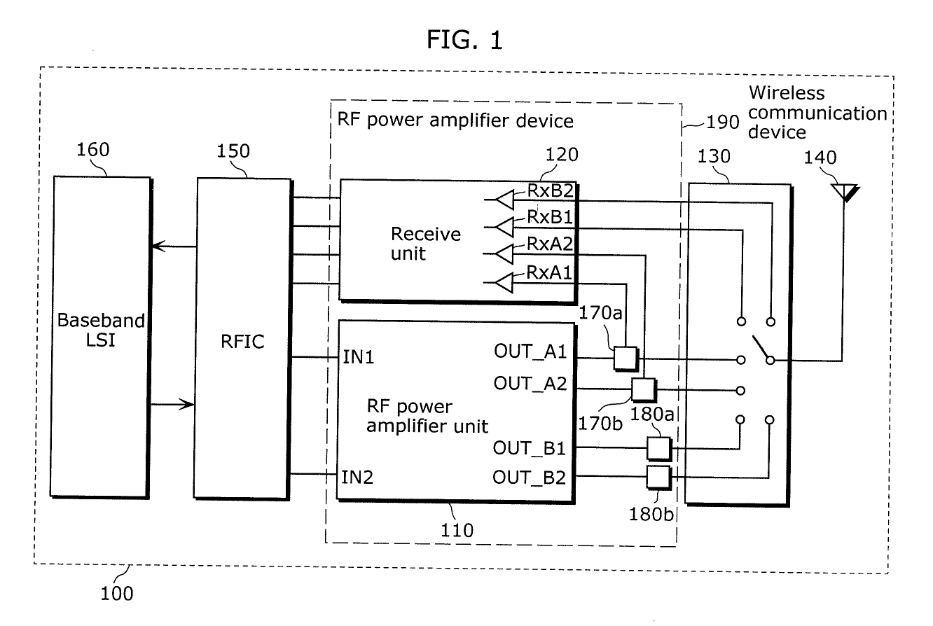

A wireless communication device including an RF power amplifier device according to Embodiment 1 is described below. FIG. 1 is a block diagram which schematically shows a configuration of the wireless communication device including the RF power amplifier device according to Embodiment 1 and a layout of the wireless communication device on a board.

A wireless communication device 100 shown in FIG. 1 supports multi bands and multi modes. For reasons of convenience of description, Embodiment 1 will be described using as an example a wireless communication device which supports four bands and three modes widely used particularly in Europe and Asia: a DCS mode in a 1.8-GHz band, a GSM mode in a 900-MHz band, a UMTS mode in a 2-GHz band, and a UMTS mode in an 850-MHz band.

The wireless communication device 100 includes an RF power amplifier unit 110, a receive unit 120, an antenna switch 130, an antenna 140, an RFIC 150, a baseband LSI 160, duplexers 170a and 170b, and filters 180a and 180b.

The RF power amplifier unit 110 amplifies an RF signal provided from the RFIC 150 and outputs the amplified RF signal as a transmit signal. The RF power amplifier unit 110 has input terminals IN1 and IN2, output terminals OUT_A1, OUT_A2, OUT_B1, and OUT_B2. Each of the input terminals IN1 and IN2 receives RF signals of relatively close frequencies regardless of modes. The output terminals OUT_A1, OUT_A2, OUT_B1, and OUT_B2 each outputs a transmit signal corresponding to each of the modes and the bands on a one-to-one basis.

For example, the input terminal IN1 is selectively provided with an RF signal for the DCS mode in the 1.8-GHz band and an RF signal for the UMTS mode in the 2-GHz band. The input terminal IN2 is selectively provided with an RF signal for the GSM mode in the 900-MHz band and an RF signal for the UMTS mode in the 850-MHz band. The output terminal OUT_A1 outputs a transmit signal for the UMTS mode in the 2-GHz band. The output terminal OUT_A2 outputs a transmit signal for the UMTS mode in the 850-MHz band. The output terminal OUT_B1 outputs a transmit signal for the DCS mode in the 1.8-GHz band. The output terminal OUT_B2 outputs a transmit signal for the GSM mode in the 900-MHz band.

The receive unit 120 receives a received signal received by the antenna 140 via the antenna switch 130, via the antenna switch 130 and the duplexer 170a, or via the antenna switch 130 and the duplexer 170b. The receive unit 120 then amplifies the received signal and sends the amplified received signal to the RFIC 150.

More specifically, the receive unit 120 has low noise amplifier (LNA) units RxA1, RxA2, RxB1, and RxB2. The LNA unit RxA1 amplifies a received signal for the UMTS mode in a receive-frequency band which corresponds to a transmit frequency of the UMTS mode in the 2-GHz band. The LNA unit RxA2 amplifies a received signal for the UMTS mode in a receive-frequency band which corresponds to a transmit frequency of the UMTS mode in the 850-MHz band. The LNA unit RxB1 receives a received signal for the DCS mode in the 1.8-GHz band from the antenna 140 via the antenna switch 130 during reception in the DCS mode in the 1.8-GHz band, and then amplifies the received signal. The LNA unit RxB2 receives a received signal for the GSM mode in the 900-MHz from the antenna 140 via the antenna switch 130 during reception in the GSM mode in the 900-MHz band, and amplifies the received signal.

The antenna switch 130 has an output terminal connected to the antenna 140, and six input terminals connected to the duplexers 170a and 170b, the filters 180a and 180b, and the receive unit 120 on a one-to-one basis. The antenna switch 130 connects one of the six input terminals to the output terminal in order to propagate transmit signals and received signals. The input terminal electrically connected to a transmit-receive terminal of the duplexer 170a is a first input switching terminal according to the present invention. The input terminal electrically connected to a transmit-receive terminal of the duplexer 170b is a second input switching terminal according to the present invention. The input terminal electrically connected to the filter 180a is a third input switching terminal according to the present invention. The input terminal electrically connected to the filter 180b is a fourth input switching terminal according to the present invention. The input terminal electrically connected to the LNA unit RxB1 is a fifth input switching terminal according to the present invention. The input terminal electrically connected to the LNA unit RxB2 is a sixth input switching terminal according to the present invention. The output terminal connected to the antenna 140 is an output switching terminal according to the present invention.

The antenna 140 transmits the transmit signal propagated via the antenna switch 130 and receives a signal transmitted from another wireless communication device as a received signal.

The RFIC 150 converts a transmit baseband signal provided from the baseband LSI 160 into an RF signal. The RFIC 150 also generates a receive baseband signal by demodulating a reception signal provided from the receive unit 120 and provides the resulting receive baseband signal for the baseband LSI 160.

The baseband LSI 160 generates the transmit baseband signal by performing signal processing, such as compression and coding, on an audio signal, and then provides the resulting transmit baseband signal for the RFIC 150. The baseband LSI 160 also converts the demodulated received signal provided from the RFIC 150 into an audio signal by performing signal processing, such as sampling, on the received signal.

Each of the duplexers 170a and 170b band-limits the transmit signal for the UMTS mode provided from the RF power amplifier unit 110, so that the transmit signal is transmitted from the antenna 140 via the antenna switch 130. Each of the duplexers 170a and 170b also band-limits the received signal from the antenna switch 130 to the receive unit 120. Specifically, the duplexer 170a is a first duplexer according to the present invention. The duplexer 170a band-limits the transmit signal for the UMTS mode in the 2-GHz band provided from the output terminal OUT_A1 of the RF power amplifier unit 110, and provides the transmit signal for the antenna switch 130. In addition, the duplexer 170a band-limits the received signal provided through the antenna 140 and the antenna switch 130 and provides the received signal for the LNA unit RxA1. Specifically, the duplexer 170b is a second duplexer according to the present invention. The duplexer 170b band-limits the transmit signal for the UMTS mode in the 850-MHz band provided from the output terminal OUT_A2 of the RF power amplifier unit 110, and then provides the transmit signal for the antenna switch 130. In addition, the duplexer 170b band-limits the received signal provided through the antenna 140 and the antenna switch 130, and provides the received signal for the LNA unit RxA2.

The filters 180a and 180b band-limit the transmit signals for the DCS mode and the GSM mode, respectively, which are provided from the RF power amplifier unit 110, and transmit the transmit signal from the antenna 140 via the antenna switch 130.

With the configuration describe above, the wireless communication device 100 supports communications in the three modes and the four bands: the DCS mode in the 1.8-GHz band, the GSM mode in the 900-MHz band, the UMTS mode in the 2-GHz band, and the UMTS mode in the 850-MHz band.

The RF power amplifier device 190 indicated by the dashed line in FIG. 1 is an RF power amplifier device according to the present invention, including the RF power amplifier unit 110, the receive unit 120, the duplexers 170a and 170b, and the filters 180a and 180b.

Next, operation of the wireless communication device 100 according to Embodiment 1 is described below. The term “RF signal” may refer to any of an RF signal, a transmit signal, or a received signal below.

Referring to FIG. 1, the operation is as follows: the antenna 140 transmits and receives RF signals, the antenna switch 130 switches transmission and received signals and mode signals provided from the antenna 140; the receive unit 120 amplifies the received signal provided from the antenna switch 130; the RFIC 150 selects from the modes and performs frequency conversion on the received signal provided from the antenna 140 and the transmit signal to be provided to the antenna 140; the baseband LSI 160 performs signal processing on the received signal provided from the RFIC 150 and the transmit signal to be provided to the RFIC 150; and the RF power amplifier unit 110 amplifies power of the transmit signal provided from the RFIC 150.

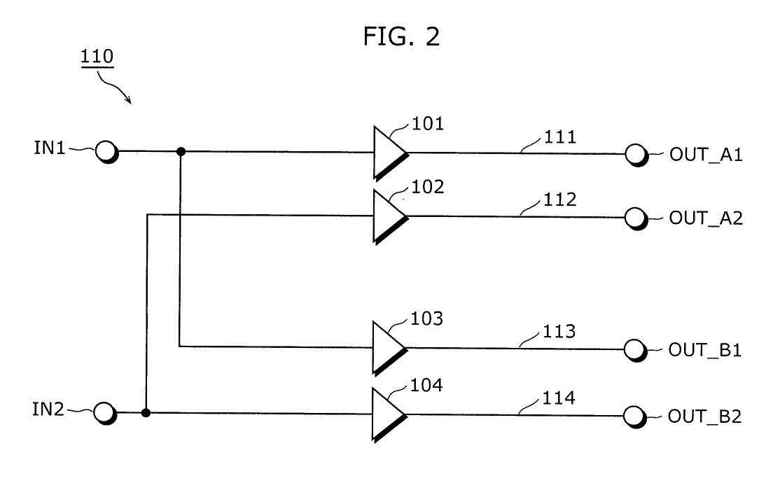

FIG. 2 is a block diagram which schematically shows a specific circuit configuration and a layout thereof on a board in the RF power amplifier unit 110.

Referring to the FIG. 2, the RF power amplifier unit 110 has the input terminals IN1 and IN2, power amplifier units 101, 102, 103, and 104, transmit lines 111 to 114, the output terminals OUT_A1, OUT_A2, OUT_B1, and the OUT_B2.

To put it another way, the RF power amplifier unit 110 amplifies power of high-frequency signals for communication modes including a first mode and a second mode which is a communication method different from the first mode, and includes: a first input terminal to which a first RF signal for the first mode and within a first frequency band and a third RF signal for the second mode and within the first frequency band are selectively provided; a second input terminal to which a second RF signal for the first mode and within a second frequency band and a fourth RF signal for the second mode and within the second frequency band are selectively provided, the second frequency band being different from the first frequency band; a first power amplifier unit configured to amplify the first RF signal provided to the first input terminal; a second power amplifier unit configured to amplify the second RF signal provided to the second input terminal; a third power amplifier unit configured to amplify the third RF signal provided to the first input terminal; a fourth power amplifier unit configured to amplify the fourth RF signal provided to the second input terminal, wherein the first to fourth power amplifier units are arranged in order of the first power amplifier unit, the second power amplifier unit, the third power amplifier unit, and the fourth power amplifier unit.

Each of the first mode and the second mode corresponds largely to an access method. For example, the first mode is a CDMA mode, and the second mode to a TDMA mode. More specifically, the first mode and the second mode correspond to communication systems for which respective access methods are used. For example, the first mode corresponds to the UMTS mode for which an access method of a CDMA mode is used, and the second mode corresponds to the DCS mode and the GSM mode for which an access method of the TDMA mode is used. The first and the second frequency bands each include bands of RF signals having frequency bands relatively close to each other among RF signals to be provided to the RF power amplifier unit 110. In Embodiment 1, for example, the first frequency band is a relatively high frequency band which includes the 2-GHz band and the 1.8-GHz band, and the second frequency band is a relatively low frequency band which includes the 850-MHz band and the 900-MHz band

The input terminal IN1 is the first input terminal according to the present invention, and provided with RF signals included in the relatively high frequency band, that is, the RF signal for the DCS mode in the 1.8-GHz band and the RF signal for the UMTS mode in the 2-GHz band. The input terminal IN2 is the second input terminal according to the present invention, and provided with RF signals included in the relatively low frequency band, that is, the RF signal for the UMTS mode in the 850-MHz band and the RF signal for the GSM mode in the 900-MHz band.

The RF signal for the UMTS mode in the 2-GHz band is the first RF signal according to the present invention. The RF signal for the UMTS mode in the 850-MHz band is the second RF signal according to the present invention. The RF signal for the DCS mode in the 1.8-GHz band is the third RF signal according to the present invention. The RF signal for the GSM mode in the 900-MHz band is the fourth RF signal according to the present invention.

Thus, among the RF signals provided to the RF power amplifier unit 110 from the RFIC 150, the RF signals in relatively close frequency bands are provided to the same input terminal regardless of modes: the RF signals of the 2-GHz band and the 1.8-GHz band into the input terminal IN1, and the RF signals of the 850-MHz band and the 900-MHz band into the input terminal IN2.

The power amplifier unit 101 has an input connected to the input terminal IN1, and amplifies the RF signal for the UMTS mode in the 2-GHz band provided to the input terminal IN1. The power amplifier unit 102 has an input connected to the input terminal IN2, and amplifies the RF signal for the UMTS mode in the 850-MHz band provided to the input terminal IN2. The power amplifier unit 103 has an input connected to the input terminal IN1, and amplifies the RF signal for the DCS mode in the 1.8-GHz band provided to the input terminal IN1. The power amplifier unit 104 has an input connected to the input terminal IN2, and amplifies the RF signal for the GSM mode in the 900-MHz band provided to the input terminal IN2.

These power amplifier units are arranged in order of the power amplifier unit 101, the power amplifier unit 102, the power amplifier unit 103, and the power amplifier unit 104.

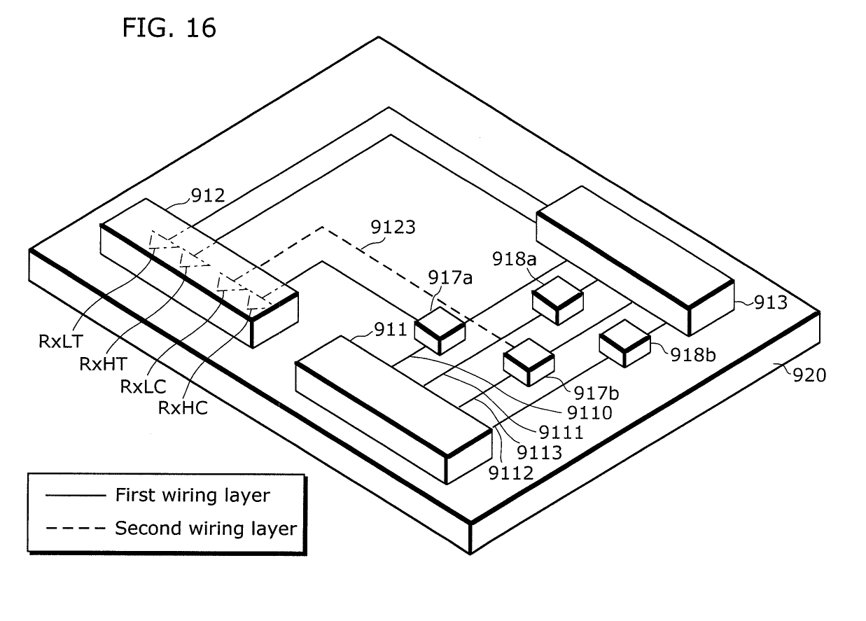

When the RF signal for the DCS mode in the 1.8-GHz band and the RF signal for the GSM mode in the 900-MHz band is transmitted, this arrangement prevents leakage of the RF signal for the DCS mode in the 1.8-GHz band and the RF signal for the GSM mode in the 900-MHz band into the receive path of the RF signal for the UMTS mode in the 2-GHz band and the receive path of the RF signal for the GSM mode in the 900-MHz band. For example, this configuration has no intersection between the second transmit path 9111 and the receive path 9123 as shown in FIG. 16, thus preventing leakage of the RF signal from the second transmit path 9111 into the receive path 9123. Degradation of reception sensitivity is thereby reduced.

The transmit line 111 is the first transmit line according to the present invention. A first end of the transmit line 111 is connected to the output of the power amplifier unit 101, and a second end is connected to the output terminal OUT_A1. The transmit line 112 is the second transmit line according to the present invention. A first end of the transmit line 112 is connected to the output of the power amplifier unit 102, and a second end is connected to the output terminal OUT_A2. The transmit line 113 is the third transmit line according to the present invention. A first end of the transmit line 113 is connected to the output of the power amplifier unit 103, and a second end is connected to the output terminal OUT_B1. The transmit line 114 is the fourth transmit line according to the present invention. A first end of the transmit line 104 is connected to the output of the power amplifier unit 104, and a second end is connected to the output terminal OUT_B2.

There is no intersection between these transmit lines 111 to 114. The receive unit 120 is disposed to be closer to the transmit lines 111 and 112 than to the transmit lines 113 and 114.

With this configuration, the RF power amplifier unit 110 amplifies, using the power amplifier unit 101, the RF signal for the UMTS mode in the 2-GHz band provided to the input terminal IN1 and outputs the resulting RF signal from the output terminal OUT_A1. In the same manner, the RF power amplifier unit 110 amplifies, using the power amplifier unit 103, the RF signal for the DCS mode in the 1.8-GHz band provided to the input terminal IN1, and outputs the resulting RF signal from the output terminal OUT_B1. In addition, the RF power amplifier unit 110 amplifies, using the power amplifier unit 104, the RF signal for the GSM mode in the 900-MHz band provided to the input terminal IN2, and outputs the resulting RF signal from the output terminal OUT_B2. In the same manner, the RF power amplifier unit 110 amplifies, using the power amplifier unit 102, the RF signal for the UMTS mode in the 850-MHz band provided to the input terminal IN2, and outputs the resulting RF signal from the output terminal OUT_A2.

The output terminals are disposed as shown in FIG. 2 so that the output terminals OUT_A1 and OUT_A2, which output the transmit signals for the UMTS mode in the 2-GHz band and in the 850-MHz band, respectively, neighbor each other with no other output terminal sandwiched therebetween, and that the output terminals OUT_B1 and OUT_B2, which output the transmit signal of the DCS mode in the 1.8-GHz band and the transmit signal for the GSM mode in the 900-MHz band, respectively, neighbor each other with no other output terminal sandwiched therebetween.

In addition, the transmit lines 111 to 114 are laid out with sufficient isolation therebetween.

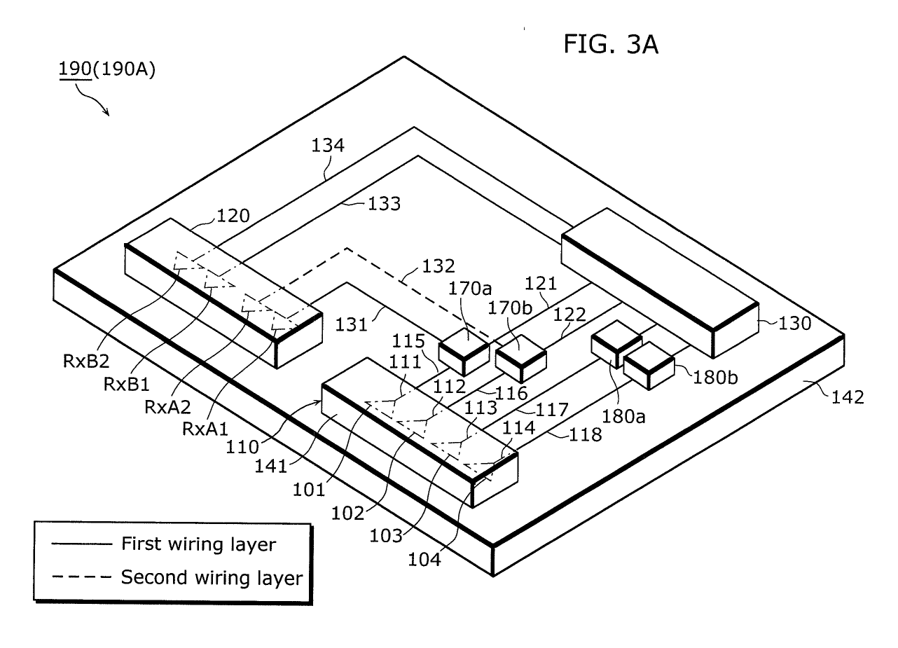

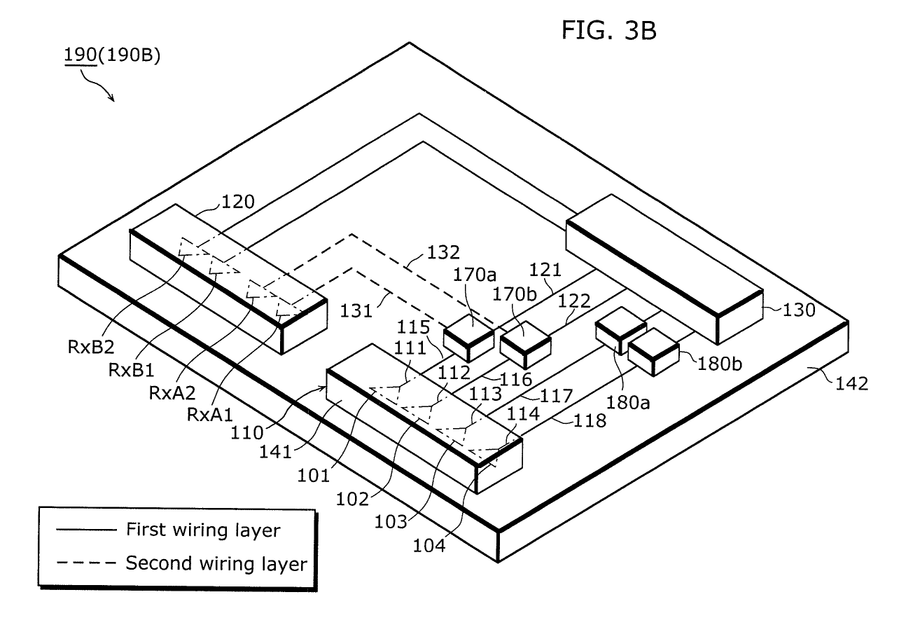

FIG. 3A shows an exemplary configuration of the RF power amplifier device 190 according to Embodiment 1, and FIG. 3B shows another exemplary configuration thereof. The RF power amplifier device 190 having the configuration shown in FIG. 3A is hereinafter referred to as an RF power amplifier device 190A to distinguish it from the RF power amplifier device 190 having the configuration shown in FIG. 3B, which is referred to as an RF power amplifier device 190B. They are collectively referred to as the RF power amplifier device(s) 190.

The RF power amplifier device 190A shown in FIG. 3A includes a semiconductor substrate 141 on which an RF power amplifier unit 110 is formed, duplexers 170a and 170b, filters 180a and 180a, an antenna switch 130, and a multilayer PCB 142 on which a receive unit 120 is mounted.

On the semiconductor substrate 141 there are formed the power amplifier units 101 to 104 and the transmit lines 111 to 114 shown in FIG. 2.

The multilayer PCB 142 is a circuit board according to the present invention. On the multilayer PCB 142, there are formed transmit lines 115 to 118, transmit-receive lines 121 and 122, and receive lines 131 to 134.

The transmit line 115 is a fifth transmit line according to the present invention. A first end of the transmit line 115 is connected to the second end of the power amplifier unit 111, and a second end is connected to a transmission terminal of the duplexer 170a. The transmit line 116 is a sixth transmit line according to the present invention. A first end of the transmit line 116 is connected to the second end of the power amplifier unit 112, and a second end is connected to a transmission terminal of the duplexer 170b. The transmit line 117 is a seventh transmit line according to the present invention. A first end of the transmit line 117 is connected to the second end of the power amplifier unit 113, and a second end is connected to a third input terminal of the antenna switch 130 via the filter 180a. The transmit line 118 is an eighth transmit line according to the present invention. A first end of the transmit line 118 is connected to the second end of the power amplifier unit 114, and a second end is connected to a fourth input terminal of the antenna switch 130 via the filter 180b.

The transmit-receive line 121 has a first end which is connected to the transmit-receive terminal of the duplexer 170a and a second end which is connected to a first input terminal of the antenna switch 130. The transmit-receive line 122 has a first end which is connected to the transmit-receive terminal of the duplexer 170b and a second end which is connected to a second input terminal of the antenna switch 130.

A receive line 131 is a first receive line according to the present invention, and has a first end which is connected to a reception terminal of the duplexer 170a and a second end which is connected to an input terminal of the LNA unit RxA1. A receive line 132 is a second receive line according to the present invention, and has a first end of the receive line 132 which is connected to a reception terminal of the duplexer 170b and a second end which is connected to an input terminal of the LNA unit RxA2. A receive line 133 has a first end which is connected to a fifth input terminal of the antenna switch 130 and which is a second end connected to a input terminal of the LNA unit RxB1. A receive line 134 has a first end which is connected to a sixth input terminal of the antenna switch 130 and a second end which is connected to a input terminal of the LNA unit RxB2. The input terminals of the LNA units RxA1, RxA2, RxB1, and RxB2 substantially serves as input terminals of the receive unit 120. The receive lines 131 to 134 are formed on the printed circuit board 142.

The transmission terminal, the transmit-receive terminal, and the reception terminal of the duplexer 170a are a first transmission terminal, a first transmit-receive terminal, and a first reception terminal according the present invention, respectively. The transmission terminal, the transmit-receive terminal, and the reception terminal of the duplexer 170b are a second transmission terminal, a second transmit-receive terminal, and a second reception terminal according the present invention, respectively.

The transmit lines 115 to 118, the transmit-receive lines 121 and 122, and the receive lines 131, 133, and 134 are formed in a first wiring layer of the multilayer PCB 142. The receive line 132 is formed in a second wiring layer, which is one of layers included in the multilayer PCB 142 and different from the first wiring layer. For example, the multilayer PCB 142 may be a four-layered circuit board, where the first wiring layer is on a front surface and the second wiring layer is on a rear surface.

The receive line 131 has no intersection with the transmit line 117 or the transmit line 118. The receive line 132 also has no intersection with the transmit line 117 or the transmit line 118.

This configuration ensures reduction in degradation of reception sensitivity due to leakage of transmission power of the RF signal for the DCS mode in the 1.8-GHz band propagated through the receive line 131 or the receive line 132 while the RF power amplifier device 190 is in communication in the DCS mode in the 1.8-GHz band. In the same manner, this configuration ensures reduction in degradation of reception sensitivity due to leakage of transmission power of the RF signal for the GSM mode in the 900-MHz band propagated via the receive line 131 or the receive line 132 while the RF power amplifier device 190 is in communication in the GSM mode in the 900-MHz band.

The receive line 131 is disposed at a distance of 100 μm or longer from both of the transmit line 117 and the transmit line 118. The receive line 132 is disposed at a distance of 100 μm or longer from both of the transmit line 117 and the transmit line 118.

This configuration enhances isolation between the receive line 131 and the transmit line 117, isolation between the receive line 131 and the transmit line 118, isolation between the receive line 132 and the transmit line 117, and isolation between the receive line 132 and the transmit line 118; thereby further reducing the degradation due to leakage of transmission power of the RF signal.

More specifically, for example, in the case linewidths of the receive line 131 and the transmit line 117 are 100 μm and the minimum distance between them is 100 μm, a capacitive component between the receive line 131 and the transmit line 117 is approximately 0.001 pF. When the capacitive component is 0.001 pF or lower, leakage of the transmission power of the 1.8-GHz band RF signal propagated through the transmit line 117 into the receive line 131 will be sufficiently reduced. This means that degradation of reception sensitivity is thereby further reduced. In the same manner, in the case linewidths of the receive line 131 and the transmit line 118 are 100 μm and the minimum distance between them is 100 μm, a capacitive component between the receive line 131 and the transmit line 118 is 0.001 pF. Leakage of the transmission power of the 900-MHz band RF signal in GSM mode propagating through the transmit line 118 is thus sufficiently reduced. The same effect will be found not only with the receive line 131 but also with the receive line 132.

The RF power amplifier device 190B shown in FIG. 3B has almost the same configuration as that of the RF power amplifier device 190A shown in FIG. 3A. The RF power amplifier devices 190A and 190B differ from each other in that the RF power amplifier device 190B has the receive line 131 formed in the second wiring layer.

This configuration reduces leakage of transmission power to the receive line 131 due to air propagation of transmission power of the RF signal for the DCS mode in the 1.8-GHz band propagated through the transmit line 117, and leakage of transmission power to the receive line 131 due to air propagation of transmission power of the RF signal for the GSM mode in the 900-MHz band propagated through the transmit line 118. The RF power amplifier device 190B thus further reduces degradation of reception sensitivity due to leakage of transmission power of the RF signal than the RF power amplifier device 190A shown in FIG. 3A.

As described above, the RF power amplifier device 190 according to Embodiment 1 is an RF power amplifier device which amplifies power of high-frequency signals for communication modes including the CDMA mode and the TDMA mode which is a communication method different from the CDMA mode, and includes: the first input terminal IN1 to which the RF signal for the UMTS mode in the 2-GHz band, which is an RF signal for the CDMA mode and within the first frequency band, and the RF signal for the DCS mode in the 1.8-GHz band, which is an RF signal for the TDMA mode and within the first frequency band, are selectively provided; the input terminal IN2 to which the RF signal for the UMTS mode in the 850-MHz band, which is an RF signal for the CDMA mode and within the second frequency band, and the RF signal for the GSM mode in the 900-MHz band, which is an RF signal for the TDMA mode and within the second frequency band, are selectively provided; the power amplifier unit 101 configured to amplify the RF signal for the UMTS mode in the 2-GHz band provided to the input terminal IN1; the power amplifier unit 102 configured to amplify the RF signal for the UMTS mode in the 850-MHz band provided to the input terminal IN2; the power amplifier unit 103 configured to amplify the RF signal for the DCS mode in the 1.8-GHz band provided to the input terminal IN1; and the power amplifier unit 104 configured to amplify the RF signal for the GSM mode in the 900-MHz band provided to the input terminal IN2, wherein these power amplifier units are arranged in order of the power amplifier unit 101, the power amplifier unit 102, the power amplifier unit 103, and the power amplifier unit 104.

With this, the RF signal for the DCS mode in the 1.8-GHz band and the RF signal for the GSM mode in the 900-MHz band which are being transmitted are prevented from leaking into the receive path of the RF signal for the UMTS mode in the 2-GHz band and into the receive path of the RF signal for the GSM mode in the 900-MHz band. Degradation of reception sensitivity is thereby reduced.

Furthermore, the configuration of the RF power amplifier unit 110 shown in FIG. 3A or FIG. 3B allows collective disposition of the connections shown in FIG. 1, that is, the connection of the output terminal OUT_A1 and the duplexer 170a and the connection of the output terminal OUT_A2 and the duplexer 170b, on the printed circuit board 142 of the wireless communication device 100; thus achieving reduction in cost and size with a simpler layout.

This also allows collective disposition of the connection of the output terminal OUT_B1 and the filter 180a and the connection of the output terminal OUT_B2 and the filter 180b on the printed circuit board 142 of the wireless communication device 100; thus achieving reduction in cost and size with a simpler layout.

The receive line 131 has no intersection with the transmit line 117 or the transmit line 118. The receive line 132 also has no intersection with the transmit line 117 or the transmit line 118. This configuration ensures reduction in degradation of reception sensitivity.

The power amplifier units 101 to 104 may be compound semiconductor heterojunction bipolar transistors or field-effect transistors.

### Variation of Embodiment 1

A wireless communication device according to the present invention may support other frequency bands or modes in addition to the four bands and the three modes described as an example for Embodiment 1: the DCS mode in the 1.8-GHz band, the GSM mode in the 900-MHz band, the UMTS mode in the 2-GHz band, and the UMTS mode in the 850-MHz band.

An RF power amplifier device according to the present variation of Embodiment 1 supports five bands and three modes including the UMTS mode in a 1.9-GHz band in addition to the bands and modes supported by the RF power amplifier device 190 according to Embodiment 1.

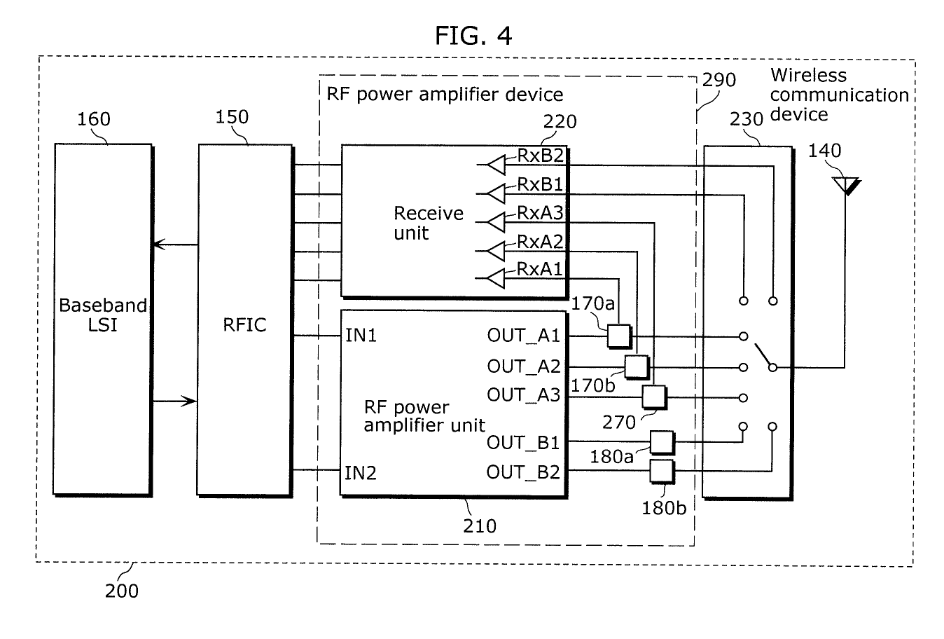

FIG. 4 is a block diagram which schematically shows a configuration of the wireless communication device including the RF power amplifier device according to the variation of Embodiment 1 and a layout of the wireless communication device on a board.

In comparison with the wireless communication device 100 shown in FIG. 1, a wireless communication device 200 shown in FIG. 4 supports five bands and three modes additionally including the UMTS mode in the 1.9-GHz band. More specifically, the wireless communication device 200 includes an antenna switch 230 and an RF power amplifier device 290 in place of the antenna switch 130 and the RF power amplifier device 190 of the wireless communication device 100, respectively.

In comparison with the antenna switch 130, the antenna switch 230 further includes an input terminal which supports the UMTS mode in the 1.9-GHz band.

In comparison with the RF power amplifier device 190 shown in FIG. 1, the RF power amplifier device 290 further includes a duplexer 270 which supports the UMTS mode in the 1.9-GHz band, and an RF power amplifier unit 210 and a receive unit 220 in place of the RF power amplifier unit 110 and the receive unit 120, respectively.

In comparison with the RF power amplifier unit 110, the RF power amplifier unit 210 further includes an output terminal OUT_A3 which supports the UMTS mode in the 1.9-GHz band.

In comparison with the receive unit 120, the receive unit 220 further includes a LNA unit RxA3 which amplifies a received signal in the receive-frequency band corresponding to the UMTS mode in the 1.9-GHz band provided from the antenna 140 via the antenna switch 230.

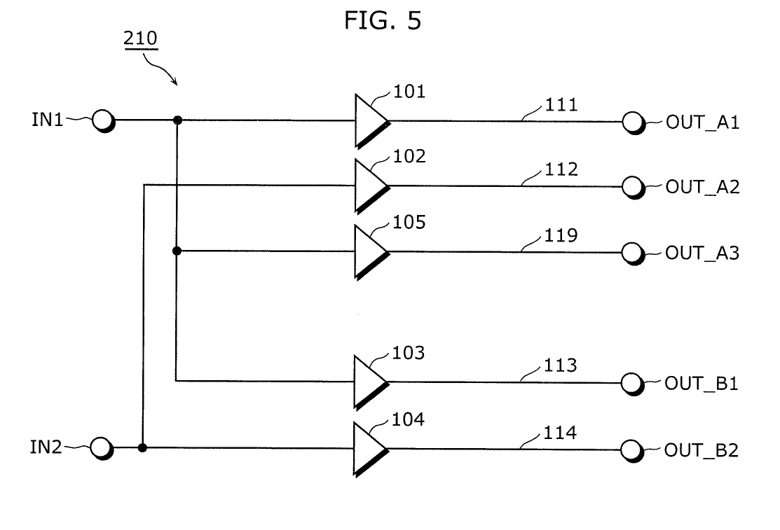

FIG. 5 is a block diagram which schematically shows a specific circuit configuration and a layout of the RF power amplifier unit 210 on a board.

In comparison with the RF power amplifier unit 110 shown in FIG. 2, the RF power amplifier unit 210 shown in FIG. 5 further includes a power amplifier unit 105, a transmit line 119, and the output terminal OUT_A3 for the UMTS mode (in this case, in the 1.9-GHz band).

The power amplifier unit 105 has an input connected to the input terminal IN1, and amplifies the RF signal for the UMTS mode in the 1.9-GHz band provided to the input terminal IN1. These power amplifier units are arranged in order of the power amplifier unit 101, the power amplifier unit 102, the power amplifier unit 105, the power amplifier unit 103, and the power amplifier unit 104.

The transmit line 119 has a first end which is connected to an output of the power amplifier unit 105, and the other end is connected to the output terminal OUT_A3. There is no intersection between the transmit lines 111 to 114 and the transmit line 119. The receive unit 220 is disposed to be closer to the transmit lines 111, 112, and 119 than to the transmit lines 113 and 114.

In comparison with the RF power amplifier unit 110, the RF power amplifier unit 210 with this configuration further amplifies the RF signal for the UMTS mode in the 1.9-GHz band provided to the input terminal IN1 using the power amplifier unit 105 and outputs the resulting RF signal from the output terminal OUT_A3.

The output terminals are configured as shown in FIG. 5 so that the output terminals OUT_A1, OUT_A2, and OUT_A3, which output the transmit signals for the UMTS mode in the 2-GHz band, the 850-MHz band, and the 1.9-GHz band, respectively, neighbor each other with no other output terminal sandwiched therebetween.

In addition, the transmit lines 111 to 114 and 119 are laid out with sufficient isolation therebetween.

For operation for the additional frequency band and mode, a transmit signal for the UMTS mode in the 1.9-GHz band is outputted from the output terminal OUT_A3 is band-limited by the duplexer 270, and then transmitted from the antenna 140 via the antenna switch 230.

In the RF power amplifier unit according to the present variation of Embodiment 1 and the wireless communication device 200 in which the RF power amplifier unit is used, the lines running from the duplexers 170a, 170b, and 270 which support the UMTS mode have no intersection with the transmit path for the DCS mode or the GSM mode; thus avoiding degradation of RF characteristics such as reception sensitivity of the receive unit and achieving reduction in size and cost with efficient wireless communication characteristics.

### Embodiment 2

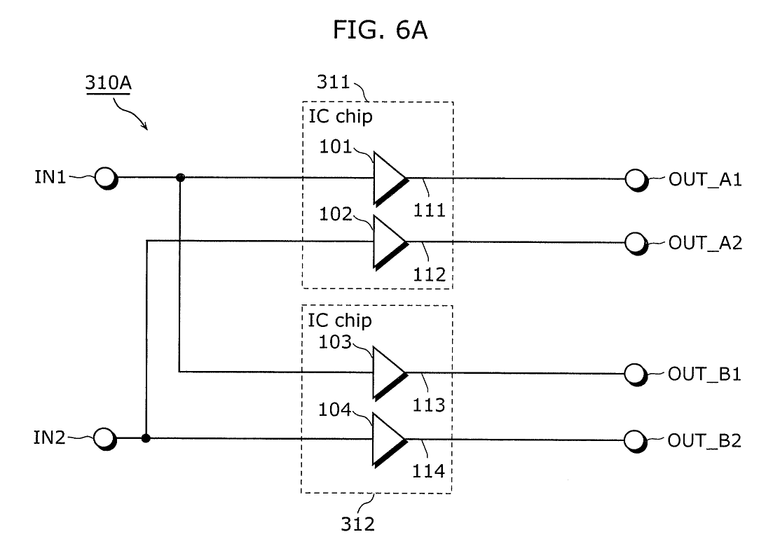

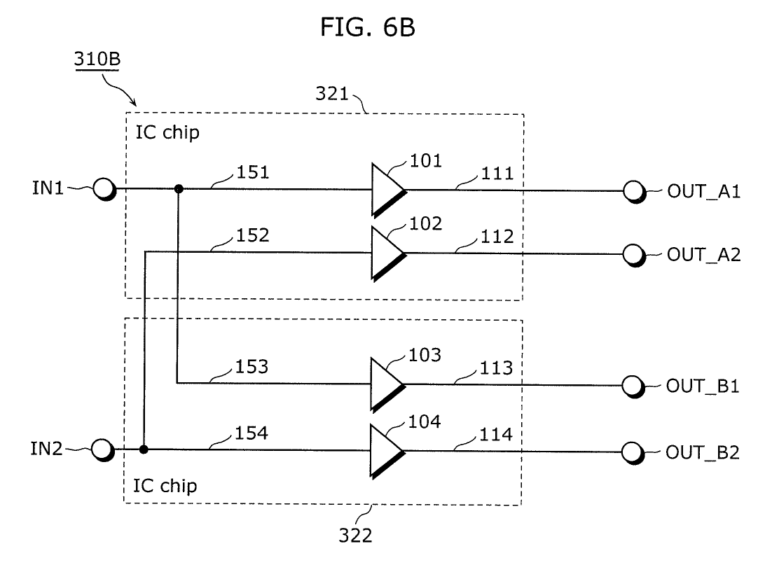

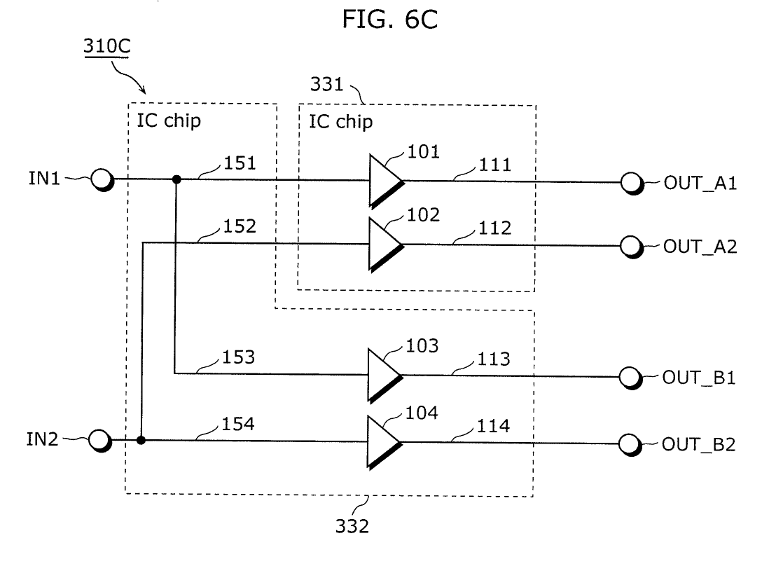

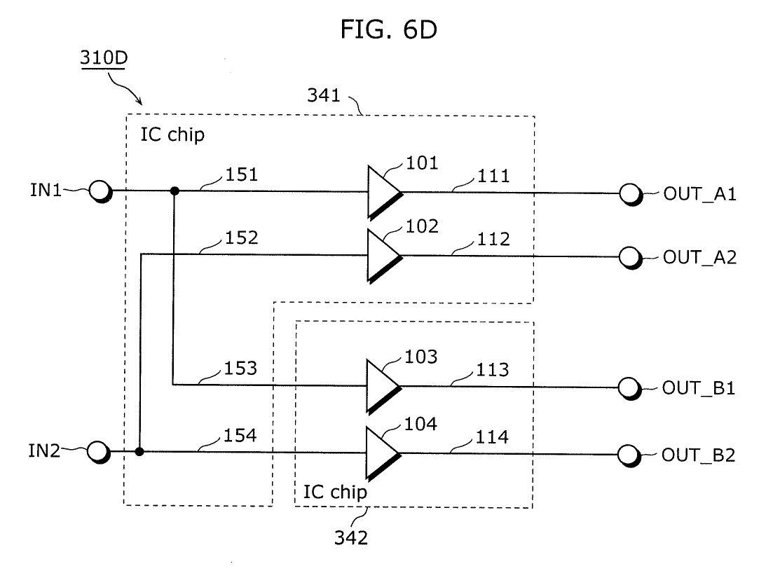

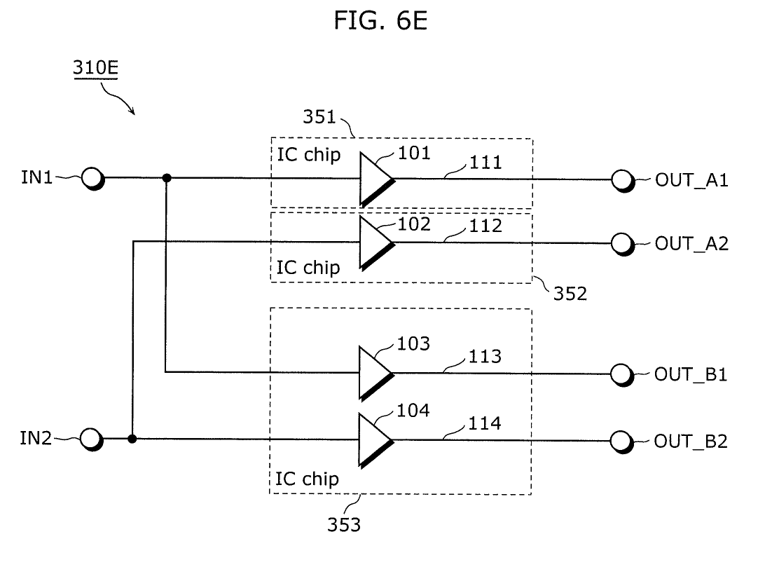

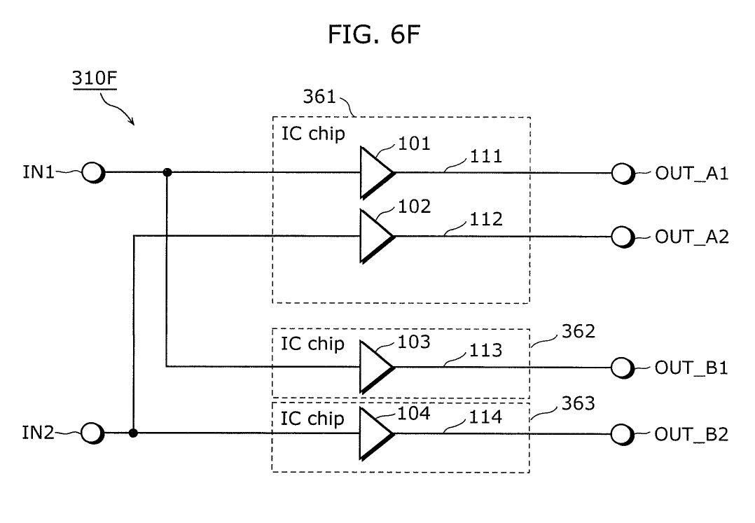

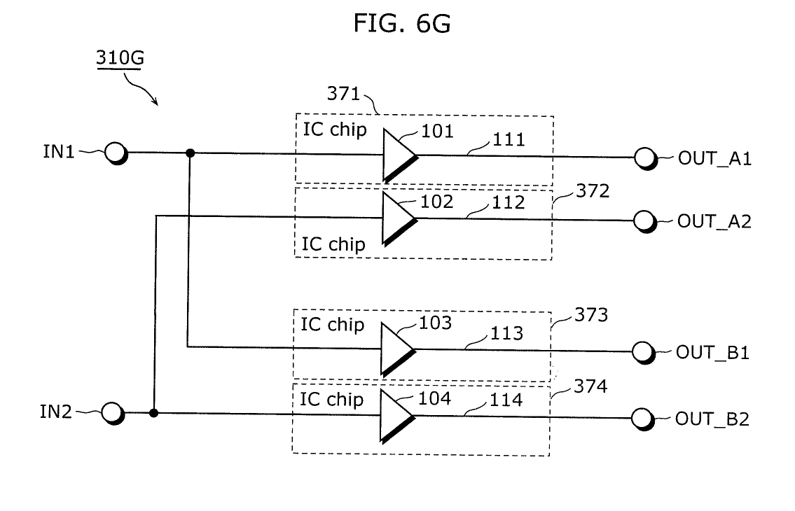

An RF power amplifier device according to Embodiment 2 is almost the same as the RF power amplifier device 190 according to Embodiment 1 but differs from it in that the RF power amplifier device has one of RF power amplifier units 310A to 310G in place of the RF power amplifier unit 110. The RF power amplifier device according to Embodiment 2 will be described below with reference to FIG. 6A to FIG. 6G.

FIG. 6A to FIG. 6G schematically illustrate circuit configurations of RF power amplifier units 310A to 310G included in the RF power amplifier device according to Embodiment 2 and layouts thereof on a board, respectively. The RF power amplifier units 310A to 310G differ from the RF power amplifier unit 110 included in the RF power amplifier device 190 according to Embodiment 1 in that the power amplifier units 101 to 104 are formed on separate semiconductor substrates.

FIG. 6A schematically shows an exemplary circuit configuration of the RF power amplifier unit included in the RF power amplifier device according to Embodiment 2 and an exemplary layout thereof on a board.

The RF power amplifier unit 310A shown in FIG. 6A differs from the RF power amplifier unit 110 included in the RF power amplifier device 190 according to Embodiment 1 in that the semiconductor substrate 141 includes IC chips 311 and 312, that the power amplifier units 101 and 102 are formed on the IC chip 311, and that the power amplifier units 103 and 104 on the IC chip 312. In other words, in the RF power amplifier unit 310A, the power amplifier units 101 and 102 for the UMTS mode are integrated on the IC chip 311, and the power amplifier unit 103 for the DCS mode and the power amplifier unit 104 for the GSM mode are integrated on the IC chip 312. These IC chips 311 and 312 are mounted on the multilayer PCB 142.

The IC chip 311 is a first semiconductor substrate according to the present invention, and the IC chip 312 is a second semiconductor substrate according to the present invention. In contrast with Embodiment 1, in which the transmit lines 111 to 114 are formed on the semiconductor substrate 141, part of each of the transmit lines 111 to 114 is formed on the semiconductor substrate 141, and the rest of the each of the transmit lines 111 to 114 is formed on the multilayer PCB 142.

Thus, in the RF power amplifier device including the RF power amplifier unit 310A according to Embodiment 2, the semiconductor substrate 141 includes the IC chips 311 and 312, the power amplifier units 101 and 102 are formed on the IC chip 311, and the power amplifier units 103 and 104 are formed on the IC chip 312.

This enhances output isolation between two of the power amplifier units formed on one IC chip and the two other power amplifier units formed on the other IC chip. Specifically, this enhances output isolation between the power amplifier unit 101 and the power amplifier unit 103, output isolation between power amplifier unit 101 and the power amplifier unit 104, output isolation between power amplifier unit 102 and the power amplifier unit 103, and output isolation between the power amplifier unit 102 and the power amplifier unit 104. This further reduces degradation of reception sensitivity due to leakage of transmission power of the RF signals amplified by the power amplifier units (the power amplifier unit 101, the power amplifier unit 102, the power amplifier unit 103, the power amplifier unit 104).

FIG. 6B schematically shows another exemplary circuit configuration of the RF power amplifier unit included in the RF power amplifier device according to Embodiment 2 and another exemplary layout thereof on a board.

The RF power amplifier unit 310B shown in FIG. 6B differs from the RF power amplifier unit 310A shown in FIG. 6A in that on the IC chip 321 there are formed the power amplifier units 101 and 102 and an input-side junction point between the power amplifier unit 101 and the power amplifier unit 103, and that on the IC chip 322 there are formed the power amplifier units 103 and 104 and an input-side junction point between the power amplifier unit 102 and the power amplifier unit 104. These IC chips 321 and 322 are mounted on the multilayer PCB 142.

More specifically, the RF power amplifier unit 310B includes an input line 151 which has a first end connected to the input terminal IN1 and a second end connected to the input terminal of the power amplifier unit 101, an input line 152 which has a first end connected to the input terminal IN2 and a second end connected to the input terminal of the power amplifier unit 102, an input line 153 which has a first end connected to the input line 151 and a second end connected to the input terminal of the power amplifier unit 103, and an input line 154 which has a first end connected to the input line 152 and a second end connected to the input terminal of the power amplifier unit 104. The first end of the input line 153 is connected to the input line 151 within the IC chip 321. The first end of the input line 154 is connected to the input line 152 within the IC chip 322.

The IC chip 321 is a first semiconductor substrate according to the present invention, and the IC chip 322 is a second semiconductor substrate according to the present invention. The input line 151 is a first input line according to the present invention. The input line 152 is a second input line according to the present invention. The input line 153 is a third input line according to the present invention. The input line 154 is a fourth input line according to the present invention.

Thus, in the RF power amplifier device including the RF power amplifier unit 310B according to Embodiment 2, the junction point between the input line 151 and the input line 153 is integrated in the IC chip 321, and the junction point between the input line 152 and the input line 154 is integrated in the IC chip 322.

This configuration allows reduction in size of the RF power amplifier device including the RF power amplifier unit 310B according to Embodiment 2 in comparison with the configuration of the RF power amplifier device including the RF power amplifier unit 310A according to Embodiment 2 shown in FIG. 6A.

FIG. 6C schematically shows another exemplary circuit configuration of the RF power amplifier unit included in the RF power amplifier device according to Embodiment 2 and another exemplary layout thereof on substrates.

The RF power amplifier unit 310C shown in FIG. 6C differs from the RF power amplifier unit 310B shown in FIG. 6B in that the RF power amplifier unit 310C has an IC chip 331 and an IC chip 332 in place of the IC chip 321 and the IC chip 331, respectively.

The IC chip 331 differs from the IC chip 321 in that in the IC chip 331 there is formed no junction point between the input line 151 and the input line 153. On the other hand, the IC chip 332 differs from the IC chip 322 in that in the IC chip 332 there is further formed the junction point between the input line 151 and the input line 153.

In other words, the difference is that in the IC chip 331 there are formed the power amplifier units 101 and 102 and that the in the IC chip 332 there are formed the power amplifier units 103 and 104, the input-side junction point between the power amplifier unit 101 and the power amplifier unit 103, and the input-side junction point between the power amplifier unit 102 and the power amplifier unit 104. These IC chips 331 and 332 are mounted on the multilayer PCB 142.

The IC chip 331 is a first semiconductor substrate according to the present invention, and the IC chip 332 is a second semiconductor substrate according to the present invention.

Thus, in the RF power amplifier device according to Embodiment 2 including the RF power amplifier unit 310C, the junction point between the input lines 151 and 153 and the junction point between the input lines 152 and 154 are integrated in the IC chip 332 in which the power amplifier units 103 and 104 are formed.

In comparison with the configuration of the RF power amplifier device including the RF power amplifier unit 310B according to Embodiment 2 shown in FIG. 6B, this configuration of the RF power amplifier device including the RF power amplifier unit 310C according to Embodiment 2 increases design flexibility of the IC chip 332. In addition, the collective configuration of the junction point between the input lines 151 and 153 and the junction point between the input lines 152 and 154 allows further reduction in size of the RF power amplifier device.

FIG. 6D schematically shows another exemplary circuit configuration of the RF power amplifier unit included in the RF power amplifier device according to Embodiment 2 and another exemplary layout thereof on a board.

The RF power amplifier unit 310D shown in FIG. 6D differs from the RF power amplifier unit 310C shown in FIG. 6C in that the RF power amplifier unit 310D has an IC chip 341and an IC chip 342 in place of the IC chip 331 and the IC chip 332, respectively.

The IC chip 341 differs from the IC chip 331 in that in the IC chip 341 there are formed the junction point between the input line 151 and the input line 153 and the junction point between the input line 152 and the input line 154. On the other hand, the IC chip 342 differs from the IC chip 332 in that in the IC chip 342 there are not formed the junction point between the input line 151 and the input line 153 or the junction point between the input line 152 and the input line 154.

In other words, the RF power amplifier unit 310D differs from the RF power amplifier unit 310C in that the junction point between the input lines 151 and 153 and the junction point between the input lines 152 and 154 are integrated in the IC chip in which the power amplifier units 101 and 102 are formed.

This configuration of the RF power amplifier device including the RF power amplifier unit 310D according to Embodiment 2 increases design flexibility of the IC chip 342. In addition, as with the RF power amplifier unit 310C shown in FIG. 6C, the collective configuration of the junction point between the input lines 151 and 153 and the junction point between the input lines 152 and 154 allows further reduction in size of the RF power amplifier device.

FIG. 6E schematically shows another exemplary circuit configuration of the RF power amplifier unit included in the RF power amplifier device according to Embodiment 2 and another exemplary layout thereof on a board.

The RF power amplifier unit 310E shown in FIG. 6E differs from the RF power amplifier unit 310A shown in FIG. 6A in that the RF power amplifier unit 310E includes an IC chip 351 and an IC chip 352 in place of the IC chip 311 and the IC chip 312, respectively, and an IC chip 353. On the IC chip 351 there is formed the power amplifier unit 101. On the IC chip 352, there is formed the power amplifier unit 102. On the IC chip 353, there are formed the power amplifier units 103 and 104. These IC chips 351 to 353 are mounted on the multilayer PCB 142.

The IC chip 351 is a first semiconductor substrate according to the present invention. The IC chip 352 is a second semiconductor substrate according to the present invention. The IC chip 353 is a third semiconductor substrate according to the present invention.

Thus, in the RF power amplifier device including the RF power amplifier unit 310E according to Embodiment 2, the semiconductor substrate 141 includes the IC chips 351 to 353, the power amplifier unit 101 is formed on the IC chip 351, the power amplifier unit 102 is formed on the IC chip 352, and the power amplifier units 103 and 104 are formed on the IC chip 353.

With this configuration, the RF power amplifier device including the RF power amplifier unit 310E is provided with enhanced output isolation between the power amplifier units 101 and 102 in comparison with the RF power amplifier device including the RF power amplifier unit 310A shown in FIG. 6A. Thus, in comparison with the configuration shown in FIG. 6A, further reduction is expected in degradation of reception sensitivity due to leakage of transmission power of the RF signals amplified by the power amplifier units (the power amplifier unit 101, the power amplifier unit 102, the power amplifier unit 103, the power amplifier unit 104).

FIG. 6F schematically shows another exemplary circuit configuration of the RF power amplifier unit included in the RF power amplifier device according to Embodiment 2 and another exemplary layout thereof on a board.

The RF power amplifier unit 310F differs from the RF power amplifier unit 310E shown in FIG. 6E in that the RF power amplifier unit 310F includes, in place of the IC chips 351 to 353, an IC chip 361 on which the power amplifier units 101 and 102 are formed, an IC chip 362 on which the power amplifier unit 103 is formed, and an IC chip 363 on which the power amplifier unit 104 is formed. These IC chips 361 to 363 are mounted on the multilayer PCB 142.

The IC chip 361 is a first semiconductor substrate according to the present invention. The IC chip 362 is a second semiconductor substrate according to the present invention. The IC chip 363 is a third semiconductor substrate according to the present invention.

Thus, in the RF power amplifier device including the RF power amplifier unit 310F according to Embodiment 2, the semiconductor substrate 141 includes the IC chips 361 to 363, the power amplifier units 101 and 102 are formed on the IC chip 361, the power amplifier unit 103 is formed on the IC chip 362, and the power amplifier unit 104 is formed on the IC chip 363.

With this configuration, the RF power amplifier device including the RF power amplifier unit 310F is provided with enhanced output isolation between the power amplifier units 103 and 104 in comparison with the RF power amplifier device including the RF power amplifier unit 310A shown in FIG. 6A. As with the configuration shown in FIG. 6E, further reduction is thus expected in degradation of reception sensitivity due to leakage of transmission power of the RF signals amplified by the power amplifier units (the power amplifier unit 101, the power amplifier unit 102, the power amplifier unit 103, the power amplifier unit 104) in comparison with the configuration shown in FIG. 6A.

FIG. 6G schematically shows another exemplary circuit configuration of the RF power amplifier unit included in the RF power amplifier device according to Embodiment 2 and the other exemplary layout thereof on a board.

The RF power amplifier unit 310G differs from the RF power amplifier unit 310F shown in FIG. 6F in that the RF power amplifier unit 310G includes, in place of the IC chips 361 to 364, an IC chip 371 on which the power amplifier unit 101 is formed, an IC chip 372 on which the power amplifier unit 102 is formed, an IC chip 373 on which the power amplifier unit 103 is formed, and an IC chip 374 on which the power amplifier unit 104 is formed. These IC chips 371 to 372 are mounted on the multilayer PCB 142.

The IC chip 371 is a first semiconductor substrate according to the present invention. The IC chip 372 is a second semiconductor substrate according to the present invention. The IC chip 373 is a third semiconductor substrate according to the present invention. The IC chip 374 is a fourth semiconductor substrate according to the present invention.

Thus, in the RF power amplifier device including the RF power amplifier unit 310G according to Embodiment 2, there are at least one semiconductor substrate 141 including the IC chips 371 to 374, the power amplifier unit 101 formed on the IC chip 371, the power amplifier unit 102 formed on the IC chip 372, and the power amplifier unit 103 formed on the IC chip 373, and the power amplifier unit 104 is formed on the IC chip 374.

With this configuration, the RF power amplifier device including the RF power amplifier unit 310G is provided with sufficient output isolation between any pair of two power amplifier units among the power amplifier units 101 to 104. As a result, further reduction is expected in degradation of reception sensitivity due to leakage of transmission power of the RF signal amplified by the power amplifier units (the power amplifier unit 101, the power amplifier unit 102, the power amplifier unit 103, the power amplifier unit 104) in comparison with the configurations shown in FIG. 6A, FIG. 6E, and FIG. 6F.

These are the exemplary RF power amplifier units included in the RF power amplifier device according to Embodiment 2 described with reference to FIG. 6A to FIG. 6G. The RF power amplifier device according to Embodiment 2 is provided with enhanced output isolation of the power amplifier units 101 to 104 formed on the different IC chips, thus reduction is expected in degradation of reception sensitivity due to leakage of transmission power of the RF signal amplified by the power amplifier units (the power amplifier unit 101, the power amplifier unit 102, the power amplifier unit 103, the power amplifier unit 104).

### Embodiment 3

An RF power amplifier device according to Embodiment 3 differs from the RF power amplifier device 190 according to Embodiment 1 in that the RF power amplifier device includes a first power amplifier unit and a second power amplifier unit each of which has m multi-stage amplifier elements (m is a natural number), third power amplifier unit and a fourth power amplifier unit each of which has n multi-stage amplifier elements (n is a natural number greater than m), m first power lines which are provided to all of the first to fourth power amplifier units so as to supply power to each of the m amplifier elements and the n amplifier elements, and (n-m) second power lines which are provided to both of the third power amplifier unit and the fourth power amplifier unit. The m first power lines have no intersection with the (n-m) second power lines. The RF power amplifier device according to Embodiment 3 can be reduced in size.

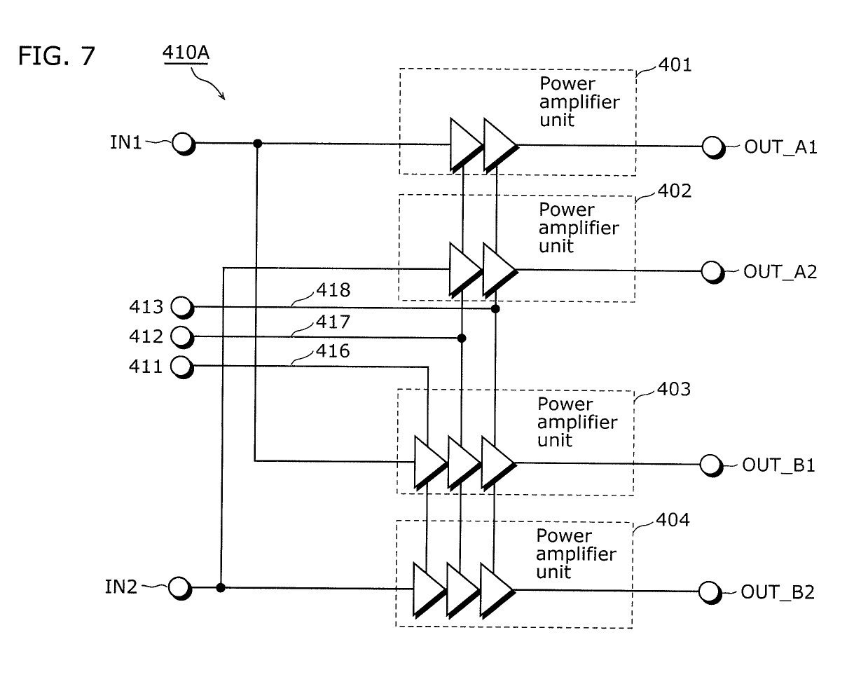

Embodiment 3 is described with reference to FIG. 7 to FIG. 10.

Although Embodiment 3 is not dependent on the number of frequency bands or modulation methods, it is described using, as an example for reasons of convenience of description, a wireless communication device which supports four bands and three modes widely used particularly in Europe and Asia: of a DCS mode in a 1.8-GHz band, a GSM mode in a 900-MHz band, a UMTS mode in a 2-GHz band, and a UMTS mode in an 850-MHz band.

FIG. 7 schematically shows a circuit configuration of the RF power amplifier unit included in the RF power amplifier device according to Embodiment 3 and a layout thereof on a board.

An RF power amplifier unit 410A shown in FIG. 7 differs from the RF power amplifier unit 110 shown in FIG. 2 in that the RF power amplifier unit 410A includes, in place of the power amplifier units 101 to 104, power amplifier units 401 and 402 each of which has m (for example, two) multi-stage amplifier elements, power amplifier units 403 and 404 each of which has n (for example, three) multi-stage amplifier elements, power terminals 411 to 413, and power lines 416 to 418.

A gain required for each of power amplifier units 401 to 404 is dependent on requirements of a transmit system for a modulation method in the mode supported by each of the power amplifier units 401 and 404. The number of stages of the amplifier elements in each of the power amplifier units 401 to 404 is determined by the gain required for each of the power amplifier units 401 to 404.

For example, in the case of the RF power amplifier unit 410A which supports three modes of the UMTS mode, the GSM mode, and the DCS mode, the power amplifier units 401 and 402 which support the UMTS mode each have two-stage amplifier elements, and the power amplifier units 403 and 404 which support the GSM mode and the DCS mode each have three-stage amplifier elements as shown in FIG. 7.

The power amplifier unit 401 is a first power amplifier unit according to the present invention. The power amplifier unit 402 is a second power amplifier unit according to the present invention. The power amplifier unit 403 is a third power amplifier unit according to the present invention. The power amplifier unit 404 is a fourth power amplifier unit according to the present invention.

The power line 416 is a second power line according to the present invention and is provided to both of the power amplifier units 403 and 404 so as to supply each of the amplifier elements included in the power amplifier units 403 and 404 with the power supplied to the power terminal 411.

The power lines 417 and 418 are first power lines according to the present invention and are provided to all of the power amplifier units 401 to 404 so as to supply the amplifier elements included in the power amplifier units 401 to 404 with the power supplied to the power terminals 412 and 413.

A feature of Embodiment 3 is that power amplifier units having amplifier elements connected in stages of the same number are arranged side by side in an RF power amplifier unit in which power amplifier units of amplifier elements connected in stages of different numbers are used in combination as in this example. In this case, these power amplifier units are arranged in order of the power amplifier unit 401, the power amplifier unit 402, the power amplifier unit 403, and the power amplifier unit 404.

Another feature of Embodiment 3 is that the power lines (the power line 417, the power line 418) provided to all of the power amplifier units (the power amplifier unit 401, the power amplifier unit 402, the power amplifier unit 403, the power amplifier unit 404) has no intersection with the power line 416 provided to a subset of the power amplifier units (the power amplifier unit 403, the power amplifier unit 404).

This configuration prevents complication of the power lines 416 to 418 with many intersections; thus achieving reduction in size of the RF power amplifier unit 410A and in turn the RF power amplifier device including the RF power amplifier unit 410A according to Embodiment 3.

A detailed configuration of the power amplifier unit 401 is described below.

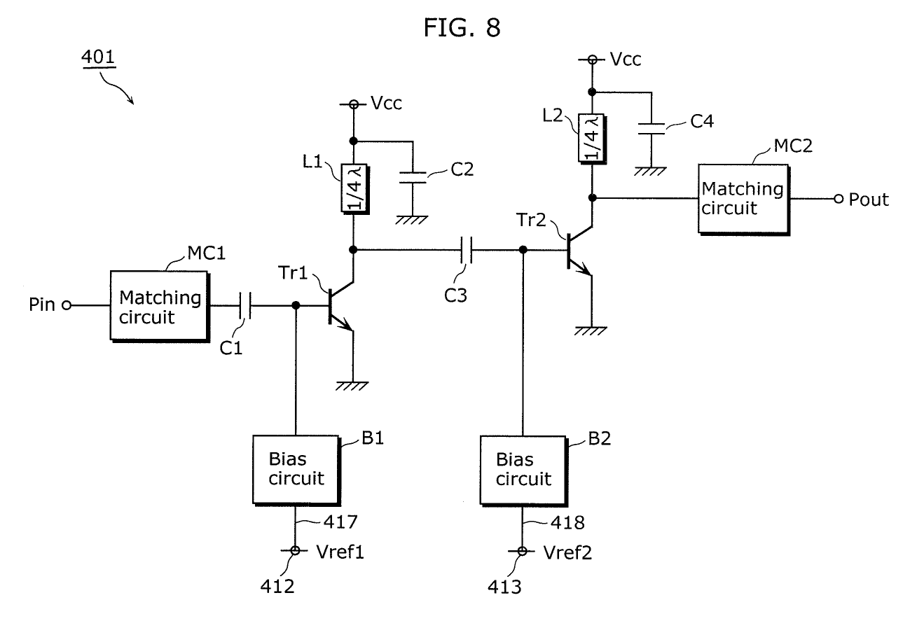

FIG. 8 is a circuit diagram which shows a circuit configuration of the power amplifier unit 401 in detail.

The power amplifier unit 401 shown in FIG. 8 has two-stage amplifier elements and amplifies an RF signal provided to an input terminal Pin to forward the amplified RF signal from the output terminal Pout. The power amplifier unit 401 has matching circuits MC1 and MC2, capacitors C1 to C4, inductors L1 and L2, a former-stage transistor Tr1, a latter-stage transistor Tr2, and bias circuits B1 and B2.

The matching circuit MC1 provides matching between an impedance (usually 50Ω) of a transmission line connected to the input of the power amplifier unit 401 via the input terminal Pin and an input impedance of the former-stage transistor Tr1.

The matching circuit MC2 provides matching between an impedance of a transmission line connected to the output side of the power amplifier unit 401 via the output terminal Pout and an output impedance of the latter-stage transistor Tr2.

The former-stage transistor Tr1 and the latter-stage transistor Tr2 are amplifier elements according to the present invention and amplify an RF signal provided to their bases to output the amplified RF signal from their collectors.

For the former-stage transistor Tr1, the base is connected to the matching circuit MC1 via the capacitor C1 for cutting a direct current, the emitter is grounded, and the collector is connected to the base of the latter-stage transistor Tr2 via the capacitor C3 for cutting a direct current. This means that the former-stage transistor Tr1 and the latter-stage transistor Tr2 are connected in multi stages. The base of the former-stage transistor Tr1 is also connected to the bias circuit B1, and the collector of the former-stage transistor Tr1 is connected to a power terminal to which a voltage Vcc is supplied via the inductor L1.

On the other hand, the collector of the latter-stage transistor Tr2 is connected to the matching circuit MC2, as well as to a power terminal to which the voltage Vcc is supplied via the inductor L2.

The bias circuit B1 generates a bias voltage of the former-stage transistor Tr1 based on a voltage Vref1 supplied from the power terminal 412 through the power line 417, and supplies the generated bias voltage to the base of the former-stage transistor Tr1.

The bias circuit B2 generates a bias voltage of the latter-stage transistor Tr2 based on a voltage Vref2 supplied from the power terminal 413 through the power line 418, and supplies the generated bias voltage to the base of the latter-stage transistor Tr2.

The inductors L1 and L2 are transmission lines which prevent leakage of an RF signal amplified by the former-stage transistor Tr1 and the latter-stage transistor Tr2 into the power terminal to which the voltage Vcc is supplied. The inductors L1 and L2 have an electrical length corresponding to, for example, a quarter wavelength.

The power amplifier unit 401 configured as described above turns on and off dependent on the voltages Vref1 and Vref2 supplied to the power terminals 412 and 413, respectively. The power amplifier unit 402 also has the same configuration as that of the power amplifier unit 401 shown in FIG. 8. The power amplifier units 403 and 404 have a configuration including one more transistor connected in multi stages than the configuration shown in FIG. 8.

A description of a configuration of the RF power amplifier unit in which power amplifier units having amplifier elements connected in stages of the same number arranged not side by side is described below as a comparative example of the RF power amplifier unit 410A included in the RF power amplifier device according to Embodiment 3.

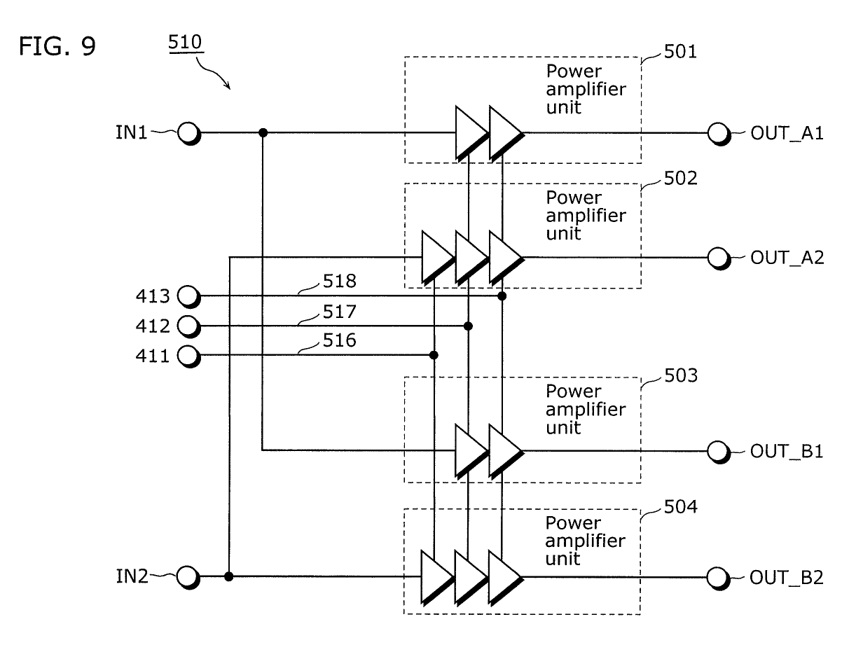

FIG. 9 schematically shows a circuit configuration of the RF power amplifier unit in the comparative example of Embodiment 3 and a layout thereof on a board.

The RF power amplifier unit 510 in the comparative example includes power amplifier units 501 and 503 having two multi-stage amplifier elements and power amplifier units 502 and 504 having three multi-stage amplifier elements. These power amplifier units are arranged in order of the power amplifier unit 501, the power amplifier unit 502, the power amplifier unit 503, and the power amplifier unit 504.

The following compares the RF power amplifier unit 410A shown in FIG. 7 and the RF power amplifier unit 510 shown in FIG. 9. In the RF power amplifier unit 410A, the power lines 416 to 418 have one intersection between them. In the RF power amplifier unit 510, the power lines 516 to 518 have three intersections between them.

Thus, complication of power lines with many intersections therebetween is prevented by arranging power amplifier units having amplifier elements connected in stages of the same number side by side as in the RF power amplifier unit 410A shown in FIG. 7.

As described above, the RF power amplifier device including the RF power amplifier unit 410A according to Embodiment 3, in which each of the amplifier elements 401 and 402 includes two multi-stage amplifier elements, and each of the amplifier elements 403 and 404 includes three multi-stage amplifier elements, and, so as to supply power to each of the two multi-stage amplifier elements included in each of the amplifier elements 401 and 402 and to each of said three multi-stage amplifier elements included in each of the amplifier elements 403 and 404, further includes: the power lines 417 and 418 provided to all of the power amplifier units 401 to 404; and the power lines 403 and 404 provided to both of the power amplifier unit. The power lines 417 and 418 have no intersection with the power line 416.

This allows simplification of the layout of the power lines 416 to 418 with fewer intersections therebetween. Thus, the RF power amplifier device according to Embodiment 3 can be reduced in size.

Although the configuration described in Embodiment 3 includes power amplifier units having two-stage amplifier elements or three-stage amplifier elements operating in the UMTS mode, the GSM mode, and the DCS mode, Embodiment 3 is not dependent on these systems or the number of stages of power amplifier elements. This is effective also in the case where power amplifier units having amplifier elements connected in stages of different numbers are arranged in other systems.

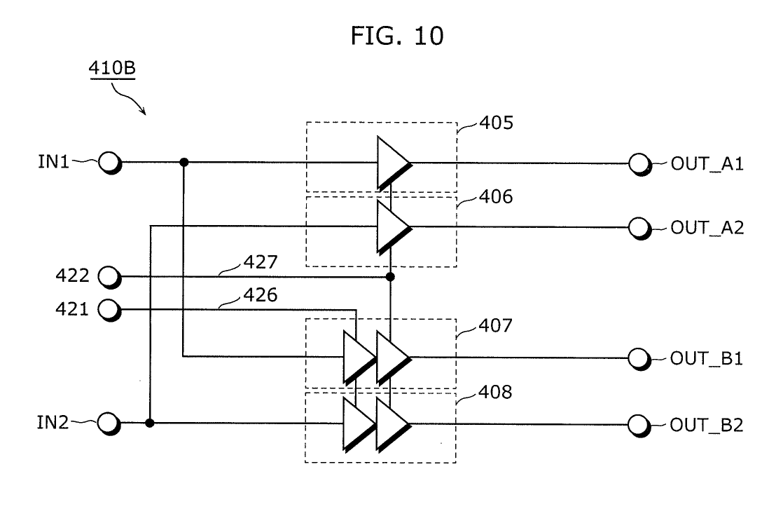

FIG. 10 schematically shows another circuit configuration of the RF power amplifier unit included in the RF power amplifier device according to Embodiment 3 and layouts thereof on a board.

The RF power amplifier unit 410B shown in FIG. 10 includes power amplifier units 405 and 406 each having one amplifier element and power amplifier units 407 and 408 each having two multi-stage amplifier elements. These power amplifier units are arranged in order of the power amplifier unit 405, the power amplifier unit 406, the power amplifier unit 407, and the power amplifier unit 408. The RF power amplifier unit 410B further includes a power line 422 provided to all of the power amplifier units 405 to 408 and a power line 426 provided to both of the power amplifier units 407 and 408. The power line 422 has no intersection with the power line 421.

As shown in FIG. 10, complication of power lines is thus prevented in the RF power amplifier unit 410B, which has the power amplifier units including one-stage or two-stage power amplifier elements, by arranging the power amplifier units having the amplifier elements connected in stages of the same number side by side, achieving reduction in size of the RF power amplifier unit.

### Embodiment 4

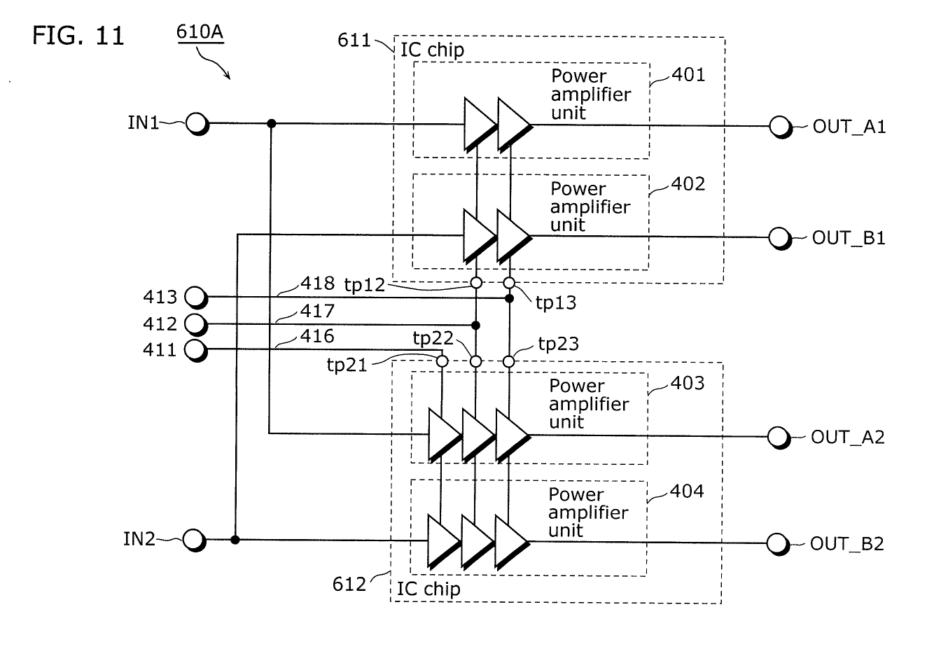

An RF power amplifier device according to Embodiment 4 is almost the same as the RF power amplifier device according to Embodiment 3 but differs from it in that the semiconductor substrate 141 includes a first semiconductor substrate and a second semiconductor substrate, that power amplifier units 401 and 402 are formed on the first semiconductor substrate, and that the power amplifier units 403 and 404 are formed on the second semiconductor substrate. The RF power amplifier device according to Embodiment 4 is described below with reference to FIG. 11 to FIG. 13. As with Embodiment 3, Embodiment 4 is not dependent on the number of frequency bands or modulation methods, it is described using, as an example for reasons of convenience of description, a wireless communication device which supports four bands and three modes of a DCS mode in a 1.8-GHz band, a GSM mode in a 900-MHz band, a UMTS mode in a 2-GHz band, and a UMTS mode in an 850-MHz band.

FIG. 11 schematically shows an exemplary circuit configuration of the RF power amplifier unit included in the RF power amplifier device according to Embodiment 4 and a layout thereof on a board.

An RF power amplifier unit 610A shown in FIG. 11 differs from the RF power amplifier unit 410A shown in FIG. 7 in that the power amplifier units 401 and 402 are formed on an IC chip 611 and the power amplifier units 403 and 404 are formed on an IC chip 612.

A feature of Embodiment 4 is that power amplifier units provided on a semiconductor substrate each have amplifier elements connected in stages of the same number.

The IC chip 611 has a power supply pad tp12 and a power supply pad tp13. The power supply pad tp12 is supplied with power from the power terminal 412 through the power line 417. The power supply pad tp13 is supplied with power from the power terminal 413 through the power line 418.

The IC chip 612 has a power supply pad tp21, a power supply pad tp22, and a power supply pad tp23. The power supply pad tp21 is supplied with power from the power terminal 411 through the power line 416. The power supply pad tp22 is supplied with power from the power terminal 412 through the power line 417. The power supply pad tp23 is supplied with power from the power terminal 413 through the power line 418.

A configuration of the RF power amplifier unit in which power amplifier units having amplifier elements connected in stages of different numbers are arranged on one semiconductor substrate is described below as a comparative example of the RF power amplifier unit 610A included in the RF power amplifier device according to Embodiment 4.

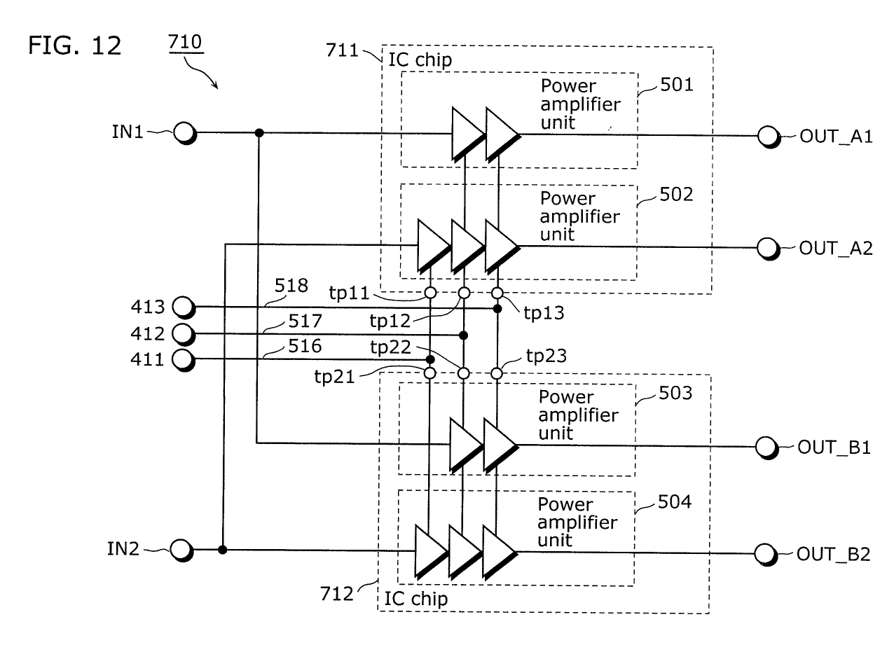

FIG. 12 schematically shows an exemplary circuit configuration of the RF power amplifier unit according to the comparative example for Embodiment 4 and a layout thereof on a board.

In the RF power amplifier unit 710 shown in FIG. 11, the power amplifier units 501 and 502, which are included in the RF power amplifier unit 510 shown in FIG. 9, are formed on an IC chip 711, and the power amplifier units 503 and 504, which are also included in the RF power amplifier unit 510, are formed on an IC chip 712.

The IC chip 711 has three power supply pads of tp11 to tp13. The IC chip 712 also has three power supply pads of tp21 to tp23.

The following compares the RF power amplifier unit 610A shown in FIG. 11 and the RF power amplifier unit 710 shown in FIG. 12. In the RF power amplifier unit 610A, the power lines 416 to 418 have one intersection between them. In the RF power amplifier unit 710, on the other hand, the power lines 516 to 518 have three intersections between them. The RF power amplifier unit 610A has fewer power supply pads than the RF power amplifier unit 610B.

Thus, complication of power lines with many intersections therebetween is prevented by arranging power amplifier units amplifier elements connected in stages of the same number in one chip as in the RF power amplifier unit 610A shown in FIG. 11. This also prevents increase in the number of the power supply pads, allowing reduction in size of the RF power amplifier unit.

As described above, in the RF power amplifier device including the RF power amplifier unit 610A according to Embodiment 4 the semiconductor substrate 141 includes the IC chips 611 and 612, the power amplifier units 401 and 402 each having two amplifier elements are formed on the IC chip 611, and the power amplifier units 403 and 404 each having three amplifier elements are formed on the IC chip 613.

This allows simplification of the layout of the power lines 416 to 418 with fewer intersections therebetween and decrease of the number of power supply pads. Thus, the RF power amplifier device can be reduced in size.

Although the configuration described in Embodiment 4 includes power amplifier units having two-stage amplifier elements and three-stage amplifier elements operating in the UMTS mode, the GSM mode, and the DCS mode, Embodiment 4 is not dependent on these systems or the number of stages of power amplifier elements. This is effective also in the case where power amplifier units having amplifier elements connected in stages of different numbers are provided as separate semiconductor substrates in other systems.

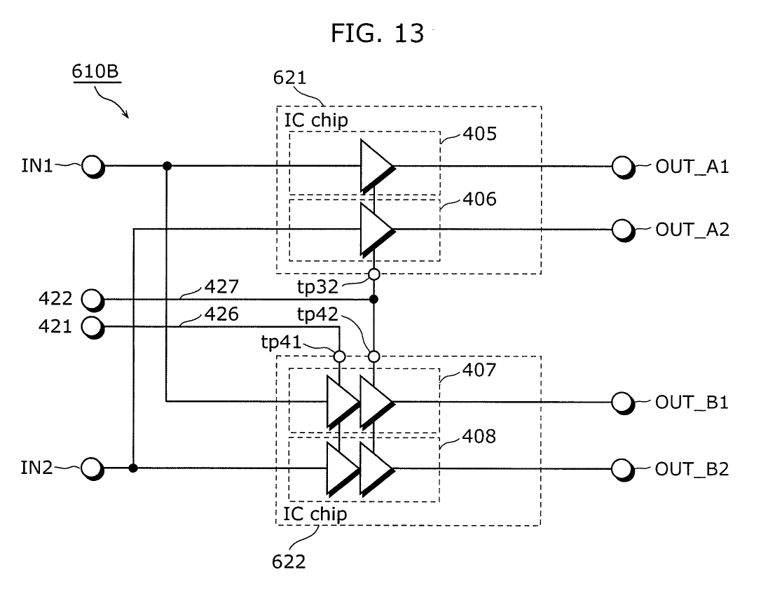

FIG. 13 schematically shows an exemplary circuit configuration of the RF power amplifier unit included in the RF power amplifier device according to Embodiment 4 and a layout thereof on a board.

An RF power amplifier unit 610B shown in FIG. 11 differs from the RF power amplifier unit 410B shown in FIG. 10 in that the power amplifier units 405 and 406 are formed on an IC chip 621 and the power amplifier units 407 and 408 are formed on an IC chip 622.

As shown in FIG. 13, complication of power lines and increase in the number of the power supply pads on the semiconductor substrates are prevented also in the RF power amplifier unit 610B, which has the power amplifier units having one-stage amplifier element and the power amplifier units having two-stage amplifier elements, by arranging the power amplifier units having amplifier elements connected in stages of the same number side by side, achieving reduction in size of the RF power amplifier unit.

Although the RF power amplifier device according to the present invention is thus described above on the basis of Embodiments 1 to 4, the present invention is not limited to these Embodiments. The scope of the present invention also includes various variations of these Embodiments unless they depart from the spirit and scope of the present invention.

For example, the RF power amplifier device may further include: a fifth power amplifier unit configured to amplify the fifth radio-frequency signal for the CDMA mode; a sixth power amplifier unit configured to amplify the sixth radio-frequency signal for the CDMA mode; and a seventh power amplifier unit configured to amplify the seventh radio-frequency signal for the CDMA mode, wherein the first frequency band and the second frequency band include five communication bands, the five communication bands correspond to the first power amplifier unit, the second power amplifier unit, and the fifth to seventh power amplifier units on a one-to-one basis, the five communication bands correspond to the first radio-frequency signal, the second radio-frequency signal, and the fifth to seventh radio-frequency signals on a one-to-one basis, and these power amplifier units are arranged in order of the fifth power amplifier unit, the sixth power amplifier unit, the seventh power amplifier unit, the first power amplifier unit, and the second power amplifier unit.

Furthermore, the present invention may be implemented not only as the RF power amplifier device described above but also as, for example, a wireless communication device 100 as shown in FIG. 1 including such an RF power amplifier device.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The RF power amplifier device according to the present invention is suitable for multi-band or multi-mode use, and thus applicable to mobile communication terminals.

What is claimed is:

1. A radio-frequency power amplifier device which amplifies power of high-frequency signals for communication modes including a first mode and a second mode which is a communication method different from the first mode, said radio-frequency power amplifier device comprising:
a first input terminal to which a first radio-frequency signal for the first mode and within a first frequency band and a third radio-frequency signal for the second mode and within the first frequency band are selectively provided;
a second input terminal to which a second radio-frequency signal for the first mode and within a second frequency band and a fourth radio-frequency signal for the second mode and within the second frequency band are selectively provided, the second frequency band being different from the first frequency band;
a first power amplifier unit configured to amplify the first radio-frequency signal provided to said first input terminal;
a second power amplifier unit configured to amplify the second radio-frequency signal provided to said second input terminal;
a third power amplifier unit configured to amplify the third radio-frequency signal provided to said first input terminal; and
a fourth power amplifier unit configured to amplify the fourth radio-frequency signal provided to said second input terminal,
wherein said first to fourth power amplifier units are arranged in order of said first power amplifier unit, said second power amplifier unit, said third power amplifier unit, and said fourth power amplifier unit.

2. The radio-frequency power amplifier device according to claim 1,
wherein said first to fourth power amplifier units are formed on at least one semiconductor substrate,
said radio-frequency power amplifier device further comprises:
a board on which said at least one semiconductor substrate is mounted;
a receive unit mounted on said board;
a first transmit line formed on said at least one semiconductor substrate and having a first end connected to an output terminal of said first power amplifier unit;
a second transmit line formed on said at least one semiconductor substrate and having a first end connected to an output terminal of said second power amplifier unit;
a third transmit line formed on said at least one semiconductor substrate and having a first end connected to an output terminal of said third power amplifier unit; and
a fourth transmit line formed on said at least one semiconductor substrate and having a first end connected to an output terminal of said fourth power amplifier unit,
said first to fourth transmit lines have no intersection with each other, and
said receive unit is disposed closer to said first transmit line and said second transmit line than to said third transmit line and said fourth transmit line.

3. The radio-frequency power amplifier device according to claim 2, further comprising:
a fifth transmit line formed on said board and having a first end connected to a second end of said first transmit line;
a sixth transmit line formed on said board and having a first end connected to a second end of said second transmit line;
a seventh transmit line formed on said board and having a first end connected to a second end of said third transmit line;
an eighth transmit line formed on said board and having a first end connected to a second end of said fourth transmit line;
a first receive line and a second receive line formed on said board and each having a first end connected to said receive unit;
a first duplexer being mounted on said board and having a first transmission terminal, a first transmit-receive terminal, and a first reception terminal, the first transmission terminal being connected to a second end of said fifth transmit line, and the first reception terminal being connected to a second end of said first receive line; and
a second duplexer being mounted on said board and having a second transmission terminal, a second transmit-receive terminal, and a second reception terminal, the second transmission terminal being connected to a second end of said sixth transmit line, and the second reception terminal being connected to a second end of said second receive line,
wherein said first receive line has no intersection with said seventh transmit line or said eighth transmit line, and
said second receive line has no intersection with said seventh transmit line or said eighth transmit line.

4. The radio-frequency power amplifier device according to claim 3,
wherein said first receive line is disposed at a distance of 100 μm or longer from both of said seventh transmit line and said eighth transmit line, and
said second receive line is disposed at a distance of 100 μm or longer from both of said seventh transmit line and said eighth transmit line.

5. The radio-frequency power amplifier device according to claim 3,
wherein said first receive line is formed in a wiring layer in which neither said seventh transmit line nor said eighth transmit line is formed, and
said second receive line is formed in a wiring layer in which neither said seventh transmit line nor said eighth transmit line is formed.

6. The radio-frequency power amplifier device according to claim 3,
wherein said at least one semiconductor substrate includes a first semiconductor substrate and a second semiconductor substrate,
said first power amplifier unit and said second power amplifier unit are formed on said first semiconductor substrate, and
said third power amplifier unit and said fourth power amplifier unit are formed on said second semiconductor substrate.

7. The radio-frequency power amplifier device according to claim 3,
wherein said at least one semiconductor substrate includes a first semiconductor substrate, a second semiconductor substrate, and a third semiconductor substrate,
said first power amplifier unit is formed on said first semiconductor substrate,
said second power amplifier unit is formed on said second semiconductor substrate, and
said third power amplifier unit and said fourth power amplifier unit are formed on said third semiconductor substrate.

8. The radio-frequency power amplifier device according to claim 3,
wherein said at least one semiconductor substrate includes a first semiconductor substrate, a second semiconductor substrate, and a third semiconductor substrate,
said first power amplifier unit and said second power amplifier unit are formed on said first semiconductor substrate,
said third power amplifier unit is formed on said second semiconductor substrate, and
said fourth power amplifier unit is formed on said third semiconductor substrate.

9. The radio-frequency power amplifier device according to claim 3,
wherein said at least one semiconductor substrate includes a first semiconductor substrate, a second semiconductor substrate, a third semiconductor substrate, and a fourth semiconductor substrate,
said first power amplifier unit is formed on said first semiconductor substrate,
said second power amplifier unit is formed on said second semiconductor substrate,
said third power amplifier unit is formed on said third semiconductor substrate, and
said fourth power amplifier unit is formed on said fourth semiconductor substrate.

10. The radio-frequency power amplifier device according to claim 3, further comprising:
a first input line having a first end connected to said first input terminal and a second end connected to an input terminal of said first power amplifier unit;
a second input line having a first end connected to said second input terminal and a second end connected to an input terminal of said second power amplifier unit;
a third input line having a first end connected to said first input line and a second end connected to an input terminal of said third power amplifier unit; and
a fourth input line having a first end connected to said second input line and a second end connected to an input terminal of said fourth power amplifier unit,
wherein the first end of said third input line is connected to said first input line in said at least one semiconductor substrate, and
the first end of said fourth input line is connected to said second input line in said at least one semiconductor substrate.

11. The radio-frequency power amplifier device according to claim 10,
wherein said at least one semiconductor substrate includes a first semiconductor substrate and a second semiconductor substrate,
said first power amplifier unit and said second power amplifier unit are formed on said first semiconductor substrate,
said third power amplifier unit and said fourth power amplifier unit are formed on said second semiconductor substrate,
the first end of said third input line is connected to said first input line in said first semiconductor substrate, and
the first end of said fourth input line is connected to said second input line in said second semiconductor substrate.

12. The radio-frequency power amplifier device according to claim 10,
wherein said at least one semiconductor substrate includes a first semiconductor substrate and a second semiconductor substrate,
said first power amplifier unit and said second power amplifier unit are formed on said first semiconductor substrate,
said third power amplifier unit and said fourth power amplifier unit are formed on said second semiconductor substrate,
the first end of said third input line is connected to said first input line in one of said first semiconductor substrate and said second semiconductor substrate, and
the first end of said fourth input line is connected to said second input line in the one of said first semiconductor substrate and said second semiconductor substrate.

13. The radio-frequency power amplifier device according to claim 3,
wherein each of said first power amplifier unit and said second power amplifier unit includes m multi-stage amplifier elements, where m is a natural number,
each of said third power amplifier unit and said fourth power amplifier unit includes n multi-stage amplifier elements, where n is a natural number greater than m,
said radio-frequency power amplifier device, so as to supply power to each of said m amplifier elements and said n amplifier elements, further comprises:
m first power lines provided to all of said first to fourth power amplifier units; and
(n-m) second power lines provided to both of said third power amplifier unit and said fourth power amplifier unit, and
said m first power lines have no intersection with said (n-m) second power lines.

14. The radio-frequency power amplifier device according to claim 13,
wherein said at least one semiconductor substrate includes a first semiconductor substrate and a second semiconductor substrate,
said first power amplifier unit and said second power amplifier unit are formed on said first semiconductor substrate, and
said third power amplifier unit and said fourth power amplifier unit are formed on said second semiconductor substrate.

15. The radio-frequency power amplifier device according to claim 3,
wherein the first mode is a Code Division Multiple Access (CDMA) mode, and the second mode is Time Division Multiple Access (TDMA) mode.

16. The radio-frequency power amplifier device according to claim 15, further comprising:
a fifth power amplifier unit configured to amplify the fifth radio-frequency signal for the first mode;
a sixth power amplifier unit configured to amplify the sixth radio-frequency signal for the first mode; and
a seventh power amplifier unit configured to amplify the seventh radio-frequency signal for the first mode,
wherein the first frequency band and the second frequency band include five communication bands,
the five communication bands correspond to said first power amplifier unit, said second power amplifier unit, and said fifth to seventh power amplifier units on a one-to-one basis, and
the five communication bands correspond to said first radio-frequency signal, said second radio-frequency signal, and said fifth to seventh radio-frequency signals on a one-to-one basis,
wherein said fifth power amplifier unit to said seventh power amplifier units, said first power amplifier unit, and said second power amplifier unit are arranged in order of said fifth power amplifier unit, said sixth power amplifier unit, said seventh power amplifier unit, said first power amplifier unit, and said second power amplifier unit.

17. A wireless communication device comprising
a radio-frequency power amplifier device according to claim 1.

18. A wireless communication device comprising the radio-frequency power amplifier device according to claim 3, said wireless communication device further comprising:
an antenna; and
an antenna switch provided between said antenna and said radio-frequency power amplifier device,
wherein said antenna switch includes:
a first input switch terminal connected to said first transmit-receive terminal;
a second input switch terminal connected to said second transmit-receive terminal;
a third input switch terminal connected to the second end of said seventh transmit line;
a fourth input switch terminal connected to the second end of said eighth transmit line;
a fifth input switch terminal and a sixth input switch terminal connected to said receive unit; and
an output switching terminal connected to said antenna, and connects said output switching terminal to one of said first to sixth input switch terminals.
